(19) United States
(12) Patent Application Publication
(10) Pub. No.: US 2024/0074181 A1
(43) Pub. Date: Feb. 29, 2024

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Linchun Wu, Wuhan (CN); Kun Zhang, Wuhan (CN); Wenxi Zhou, Wuhan (CN); Cuicui Kong, Wuhan (CN); Shuangshuang Wu, Wuhan (CN); Zhiliang Xia, Wuhan (CN); Zongliang Huo, Wuhan (CN)

(21) Appl. No.: 17/896,959

(22) Filed: Aug. 26, 2022

(51) Int. Cl. H01L 27/11582; H01L 23/528; H01L 27/11519; H01L 27/11556; H01L 27/11565

(52) U.S. Cl. CPC H01L 27/11582; H01L 23/5283; H01L 27/11519; H01L 27/11556; H01L 27/11565

(57) ABSTRACT

A memory device includes a stack structure, channel structures, and a slit structure. The stack structure includes interleaved conductive layers and dielectric layers, and the conductive layers include a plurality of word lines. Each of the channel structures extends vertically through the stack structure. The slit structure extends vertically through the stack structure. An outer region of the stack structure includes a staircase structure, and the interleaved conductive layers and dielectric layers in a bottom portion of the stack structure are wider than the interleaved conductive layers and dielectric layers in a top portion of the stack structure. A first outer width of the slit structure in the bottom portion of the stack structure is greater than a second outer width of the slit structure in the top portion of the stack structure.

### BACKGROUND

Embodiments of the present disclosure relate to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit. A 3D memory architecture can address the density limitation in planar memory cells.

### SUMMARY

Embodiments of 3D memory devices and methods for forming the same are disclosed herein.

In one aspect, a 3D memory device is disclosed. The 3D memory device includes a memory device. The memory device includes a stack structure, channel structures, and a slit structure. The stack structure includes interleaved conductive layers and dielectric layers, and the conductive layers include a plurality of word lines. Each of the channel structures extends vertically through the stack structure. The slit structure extends vertically through the stack structure. An outer region of the stack structure includes a staircase structure, and the interleaved conductive layers and dielectric layers in a bottom portion of the stack structure are wider than the interleaved conductive layers and dielectric layers in a top portion of the stack structure. A first outer width of the slit structure in the bottom portion of the stack structure is greater than a second outer width of the slit structure in the top portion of the stack structure.

In some implementations, the 3D memory device further includes a peripheral device disposed above the memory device and in electric contact with the plurality of channel structures.

In some implementations, the 3D memory device further includes an interconnect structure disposed below the stack structure. The interconnect structure and the peripheral device are disposed at opposite sides of the stack structure.

In some implementations, the 3D memory device further includes a plurality of contact structures extending vertically through the stack structure. Each of the plurality of contact structures is in electric contact with one of the plurality of word lines, respectively.

In some implementations, the word lines are in electric contact with the contact structures at an edge portion of the word lines, and the edge portion of the word lines has a thickness greater than other portions of the word lines.

In another aspect, a system is disclosed. The system includes a 3D memory device configured to store data, and a memory controller coupled to the 3D memory device and configured to control operations of the 3D memory device. The 3D memory device includes a memory device. The memory device includes a stack structure, a plurality of channel structures, and a slit structure. The stack structure includes interleaved conductive layers and dielectric layers, and the conductive layers include a plurality of word lines. Each of the plurality of channel structures extends vertically through the stack structure. The slit structure extends vertically through the stack structure. An outer region of the stack structure includes a staircase structure, and the interleaved conductive layers and dielectric layers in a bottom portion of the stack structure are wider than the interleaved conductive layers and dielectric layers in a top portion of the stack structure. A first outer width of the slit structure in the bottom portion of the stack structure is greater than a second outer width of the slit structure in the top portion of the stack structure.

In still another aspect, a method for forming a 3D memory device is disclosed. A dielectric stack including a plurality of first dielectric layers and a plurality of first sacrificial layers interleaved is formed on a substrate. A plurality of channel structures is formed extending vertically through the dielectric stack. A first opening is formed from a top side of the dielectric stack. A second opening aligning and connecting the first opening is formed from a bottom side of the dielectric stack. The plurality of first sacrificial layers are replaced with a plurality of word lines. A slit structure is formed in the first opening and the second opening.

In some implementations, an outer width of the second opening is greater than an outer width of the first opening.

In some implementations, a first semiconductor layer is formed on the substrate, a second dielectric layer is formed in the first semiconductor layer, and the dielectric stack including the plurality of first dielectric layers and the plurality of first sacrificial layers interleaved is formed on the first semiconductor layer and the second dielectric layer.

In some implementations, a trench is formed in the first semiconductor layer, and the second dielectric layer is formed in the trench.

In some implementations, a staircase structure is formed at an outer region of the dielectric stack, the first opening is formed from the top side of the dielectric stack, the first opening vertically aligning the second dielectric layer, and a second sacrificial layer is formed in the first opening.

In some implementations, the second sacrificial layer includes silicon carbide.

In some implementations, a third dielectric layer is formed above the staircase structure, and a plurality of contact structures extending are formed vertically through the third dielectric layer, each of the plurality of contact structures in contact with one of the plurality of first sacrificial layers.

In some implementations, a peripheral device is formed on the dielectric stack in electric contact with the plurality of channel structures and the plurality of contact structures.

In some implementations, the substrate and the first semiconductor layer are removed, a second semiconductor layer is formed surrounding the second dielectric layer, the second dielectric layer and a portion of the dielectric stack are removed from the bottom side of the dielectric stack, and the second sacrificial layer in the first opening is removed from the bottom side of the dielectric stack.

In some implementations, an etch operation is performed to remove the second dielectric layer and the portion of the dielectric stack until being stopped by the second sacrificial layer.

In some implementations, the plurality of first sacrificial layers are removed through the first opening and the second opening to form a plurality of cavities, and the plurality of word lines are formed in the plurality of cavities.

In some implementations, an outer width of a bottom portion of the slit structure is greater than an outer width of a top portion of the slit structure.

In yet another aspect, a method for forming a 3D memory device is disclosed. A first semiconductor layer is formed on a substrate. A first dielectric layer is formed in the first semiconductor layer. A dielectric stack including a plurality of second dielectric layers and a plurality of first sacrificial layers interleaved is formed on the first dielectric layer and the first semiconductor layer. A plurality of channel structures are formed extending vertically through the dielectric stack. A second sacrificial layer is formed extending vertically in a top portion of the dielectric stack. The first dielectric layer and the second sacrificial layer are removed from a bottom side of the dielectric stack to form a first opening. A slit structure is formed in the first opening.

In some implementations, a trench is formed in the first semiconductor layer, and the second dielectric layer is formed in the trench.

In some implementations, a second opening is formed extending vertically in the top portion of the dielectric stack, the second opening overlaps the first dielectric layer in a plan view of the 3D memory device, and the second sacrificial layer is formed in the second opening.

In some implementations, the second sacrificial layer includes silicon carbide.

In some implementations, the substrate and the first semiconductor layer are removed, a second semiconductor layer is formed surrounding the first dielectric layer, the first dielectric layer and a portion of the dielectric stack are removed from the bottom side of the dielectric stack, and the second sacrificial layer in the top portion of the dielectric stack is removed from the bottom side of the dielectric stack.

In some implementations, the second semiconductor layer is thinned, a mask layer is formed over the second semiconductor layer and the first dielectric layer, a third dielectric layer is formed over the mask layer, a planarization operation is performed to remove a portion of the third dielectric layer and a portion of the mask layer, and an etch operation is performed to remove the first dielectric layer and the second sacrificial layer from the bottom side of the dielectric stack.

In some implementations, the first dielectric layer, a portion of the dielectric stack, and the second sacrificial layer are removed from the bottom side of the dielectric stack.

In some implementations, a staircase structure is formed at an outer region of the dielectric stack.

In some implementations, a fourth dielectric layer is formed above the staircase structure, and a plurality of contact structures are formed extending vertically through the fourth dielectric layer, each of the plurality of contact structures in contact with one of the plurality of first sacrificial layers.

In some implementations, a peripheral device is formed on the dielectric stack in electric contact with the plurality of channel structures and the plurality of contact structures.

In some implementations, the plurality of first sacrificial layers are replaced with a plurality of word lines.

In some implementations, the plurality of first sacrificial layers are removed through the first opening and the second opening to form a plurality of cavities, and the plurality of word lines are formed in the plurality of cavities.

In some implementations, an outer width of a bottom portion of the slit structure is greater than an outer width of a top portion of the slit structure.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1A-1B illustrate a cross-section and a plan view of an exemplary 3D memory device, according to some aspects of the present disclosure.

FIGS. 2-25 illustrate cross-sections of an exemplary 3D memory device at different stages of a manufacturing process, according to some aspects of the present disclosure.

FIG. 26 illustrates a flowchart of an exemplary method for forming a 3D memory device, according to some aspects of the present disclosure.

FIG. 27 illustrates a flowchart of another exemplary method for forming a 3D memory device, according to some aspects of the present disclosure.

FIG. 28 illustrates a block diagram of an exemplary system having a memory device, according to some aspects of the present disclosure.

FIG. 29A illustrates a diagram of an exemplary memory card having a memory device, according to some aspects of the present disclosure.

FIG. 29B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

A 3D semiconductor device can be formed by stacking semiconductor memory layers, structures, wafers or dies and interconnecting them vertically so that the resulting structure acts as a single device to achieve performance improvements at reduced power and a smaller footprint than planar processes. However, as the number of 3D memory layers continues to increase, the control of the gate line slit structure profile becomes more and more difficult. The abnormality of the gate line slit structure may cause a plurality of deficiencies, e.g., the metal residue and the word line current leakage. The present application is introduced to overcome these deficiencies.

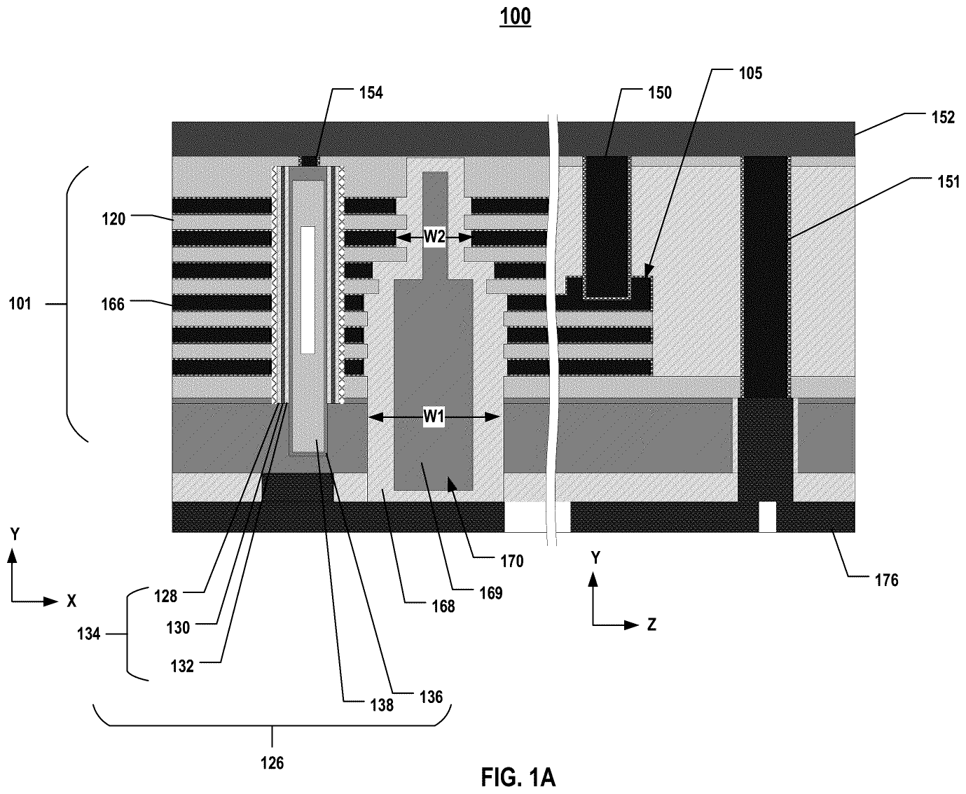

FIG. 1A illustrates a cross-section of an exemplary 3D memory device 100, according to some aspects of the present disclosure. For the purpose of better describing the present disclosure, the cross-sections of a core array region and a staircase region are illustrated in the same drawings in the present disclosure, and the coordinates of x-direction and z-direction are noted in FIG. 1A to show the relationship of the cross-sections of the core array region and the staircase region. FIG. 1B illustrate a plan view of an exemplary 3D memory device 100, according to some aspects of the present disclosure. As shown in FIG. 1B, 3D memory device 100 may be divided into a staircase region 194, a core array region 192, and a transitional region 196 (if any) between staircase region 194 and core array region 192.

As shown in FIG. 1A, 3D memory device 100 includes a stack structure 101 and a channel structure 126 extending through stack structure 101 along the y-direction. Stack structure 101 may include conductive layers 166 and dielectric layers 120, and each conductive layer 166 interleaves with each dielectric layer 120, referred to as a conductive/dielectric layer pair. In some implementations, dielectric layers 120 may include dielectric materials including, but not limited to, silicon oxide, silicon nitride, silicon oxynitride, or any combination thereof. In some implementations, conductive layers 166 may form the word lines and may include conductive materials including, but not limited to, tungsten (W), cobalt (Co), copper (Cu), aluminum (Al), polysilicon, doped silicon, silicides, or any combination thereof.

In core array region 192, 3D memory device 100 may include one or more channel structures 126 extending in stack structure 101 along the y-axis. In the staircase region 194, 3D memory device 100 may include a plurality of stairs extending along the lateral direction (e.g., z-direction).

Channel structure 126 may extend through stack structure 101. Here, the “bottom” or the “top” of channel structure 126 refer to the relative position shown in FIG. 1A, and it is understood that when 3D memory device 100 is flipped over, the relative positions of the “bottom” or the “top” will be changed accordingly. In some implementations, channel structure 126 may include a channel layer 136 and a memory film 134 formed over channel layer 136. The meaning of “over” here, besides the explanation stated above, should also be interpreted “over” something from the top side or from the lateral side. In some implementations, channel structure 126 may also include a dielectric core 138 in the center of channel structure 126. In some implementations, memory film 134 may include a tunneling layer 132 over channel layer 136, a storage layer 130 over tunneling layer 132, and a blocking layer 128 over storage layer 130.

Dielectric core 138, channel layer 136, tunneling layer 132, storage layer 130, and blocking layer 128 are arranged radially from the center toward the outer surface of channel structure 126 in this order, according to some implementations. In some implementations, tunneling layer 132 may include silicon oxide, silicon oxynitride, or any combination thereof. In some implementations, storage layer 130 may include silicon nitride, silicon oxynitride, silicon, or any combination thereof. In some implementations, blocking layer 128 may include silicon oxide, silicon oxynitride, high dielectric constant (high-k) dielectrics, or any combination thereof. In one example, the memory film 134 may include a composite layer of silicon oxide/silicon oxynitride (or silicon nitride)/silicon oxide (ONO).

As shown in FIG. 1A, 3D memory device 100 further includes a staircase structure 105 on one or more sides of stack structure 101 for purposes such as word line fan-out. In some implementations, staircase structure 105 may not be disposed on the side of stack structure 101, e.g., disposed in the center of stack structure 101, and staircase structure 105 shown in FIG. 1A illustrates one of the possible structures. In some implementations, contact structures 150 may land on staircase structure 105 along the y-direction. In some implementations, the outer region of stack structure 101 may include multiple staircase structures 105. The corresponding edges of the conductive/dielectric layer pairs along the vertical direction away from the bottom of stack structure 101 (the positive y-direction) can be staggered laterally toward channel structure 126. In other words, the edges of stack structure 101 in staircase structures 105 can be tilted toward the inner region of stack structure 101. In some implementations, the length of the conductor/dielectric layer pairs along the x-direction increases from the top to the bottom.

In some implementations, the top layer in each level of staircase structure 105 (e.g., each conductor/dielectric layer pair in FIG. 1A) is conductive layer 166 for interconnection with contact structure 150 in the vertical directions (the y-direction). In some implementations, the adjacent levels of staircase structure 105 are offset by a nominally same distance in the vertical direction and a nominally same distance in the lateral direction. Each offset thus can form a “landing area” for interconnection with the word lines of 3D memory device 100 in the vertical direction. In some implementations, the thickness of conductive layer 166 in the landing area may be greater than other areas, as shown in FIG. 1A. In some implementations, the landing area and the dielectric layer may have a gap along the z-direction, as shown in FIG. 1A.

3D memory device 100 further includes a slit structure 170. Slit structures 170 may extend along the y-direction through stack structure 101 and may also extend along the z-direction to separate stack structure 101 into multiple fingers or multiple blocks. In some implementations, slit structures 170 may be used as a contact path and may include a slit contact 169, formed by filling the slit opening with conductive materials including but not limited to, W, Co, Cu, Al, polysilicon, silicides, or any combination thereof. Slit structures 170 may further include a composite spacer 168 disposed laterally between slit contact 169 and stack structure 101 to electrically insulate slit contact 169 from surrounding conductive layers 166 of the stack structure. In some implementations, composite spacer 168 may include silicon oxide. In some implementations, slit contact 169 may be further extended or in contact with other distribution layers to form the contact path. In some implementations, slit structures 170 may be a supporting structure including dielectric materials.

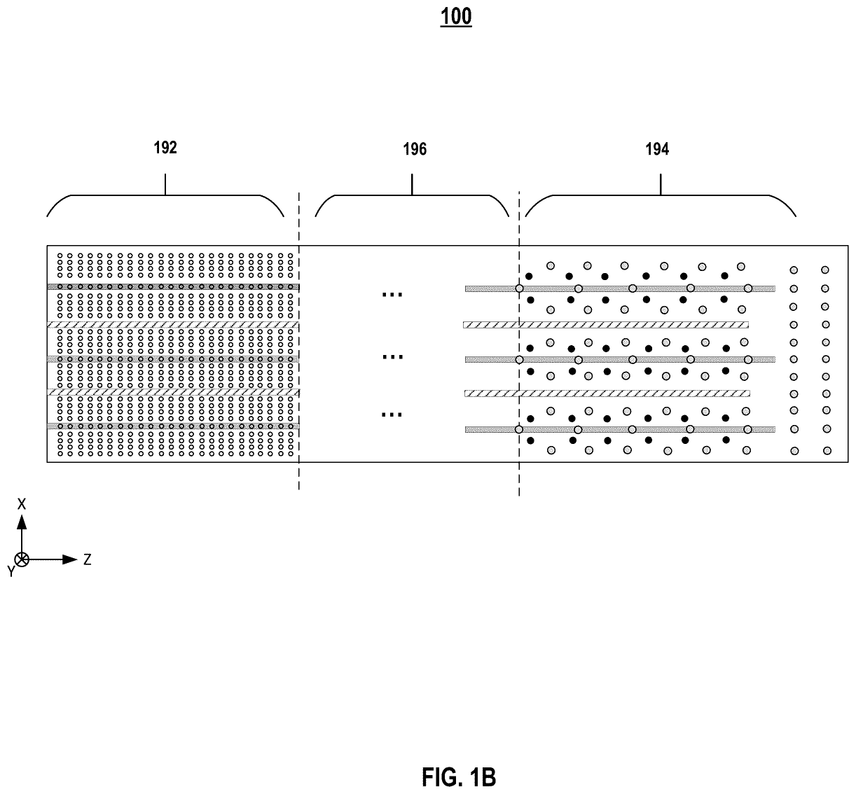

In some implementations, as shown in FIG. 1A, the top portion and the bottom portion of slit structure 170 may have different outer widths. In some implementations, two openings may be formed from the top side and the bottom side of stack structure 101. A dielectric layer may be first formed in the substrate before forming stack structure 101, and after forming a first opening from the front side of stack structure 101, a sacrificial layer may be filled in the first opening. In some implementations, the substrate may further include other layers, such as a semiconductor layer 106 and a dielectric layer 104, as shown in FIG. 2. When forming a second opening from the bottom side of stack structure 101, the dielectric layer and/or the sacrificial layer may perform a self-alignment operation to form the second opening, and a complete slit opening will be formed when the second opening has been formed and the second opening is connected with the first opening. Here, the “front side” and the “bottom side” are referred to with respect to the y-direction when the substrate is on the bottom. The detailed operations of forming slit structure 170 will be discussed later. By forming the slit openings from both sides of stack structure 101, the difficulty of the etch operation to form slit structure 170 can be reduced, and slit structure 170 profile can be improved as well.

As shown in FIG. 1A, the top portion and the bottom portion of slit structure 170 may have different outer widths. Because two openings are formed from the front side and the backside of stack structure 101, the sidewalls of slit structure 170 may not be a smooth structure and may have a bent or stair-like structure. In some implementations, an outer width W1 of slit structure 170 in the bottom portion of stack structure 101 is greater than an outer width W2 of slit structure 170 in the top portion of stack structure 101. In some implementations, W1 may be the average width of the bottom portion of slit structure 170. In some implementations, W1 may be the widest portion of the bottom portion of slit structure 170. In some implementations, W2 may be the average width of the top portion of slit structure 170. In some implementations, W2 may be the widest portion of the top portion of slit structure 170.

In some implementations, 3D memory device 100 may further include a peripheral device 152 disposed above stack structure 101 and in electric contact with the plurality of channel structures 126. In some implementations, peripheral device 152 may be disposed under or aside stack structure 101, which is not limited here. In some implementations, peripheral device 152 may be electrically connected to channel structures 126 through the peripheral contacts 154. In some implementations, 3D memory device 100 may further include an interconnect structure 176 disposed below stack structure 101. Interconnect structure 176 and the peripheral device 152 are disposed at opposite sides of stack structure 101, and may be electrically connected through a contact 151. Interconnect structure 176 and contact 151 may electrically connect peripheral device 152 to the bottom end of channel structure 126. In some implementations, 3D memory device 100 may further include a plurality of contact structures 150 extending vertically to stack structure 101. Each of the plurality of contact structures 150 is in electric contact with one of the plurality of word lines, respectively. In some implementations, the word lines (conductive layers 166) are in electric contact with contact structures 150 at an edge portion of the word lines, and the edge portion of the word lines has a thickness greater than other portions of the word lines.

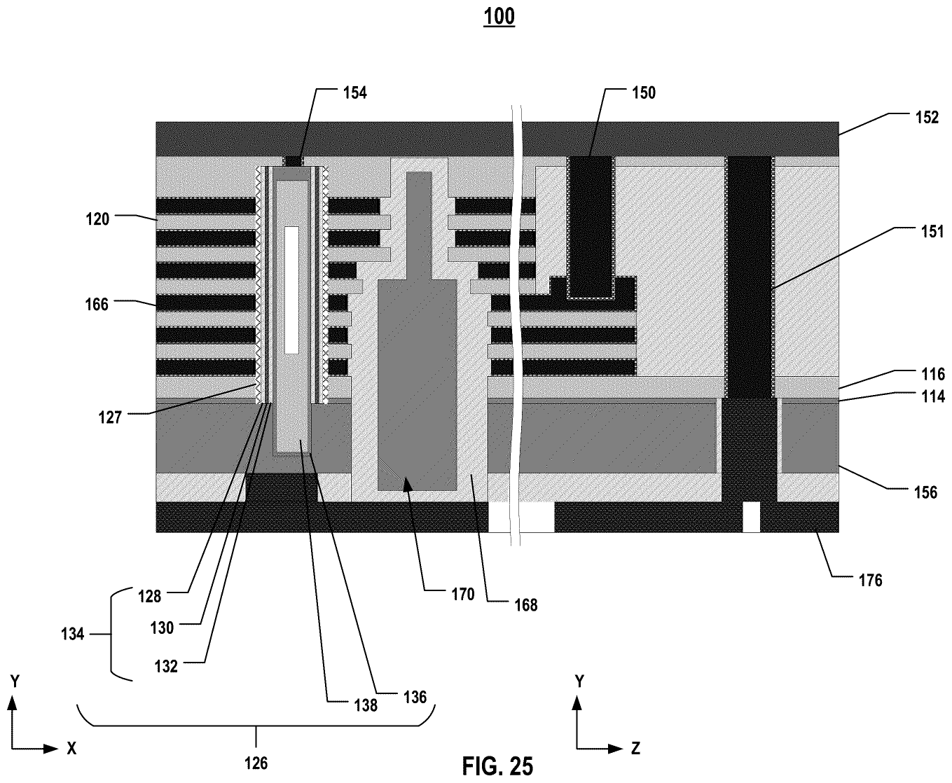

FIGS. 2-25 illustrate cross-sections of 3D memory device 100 at different stages of a manufacturing process, according to some aspects of the present disclosure. FIG. 26 illustrates a flowchart of a method 200 for forming 3D memory device 100, according to some aspects of the present disclosure. For the purpose of better describing the present disclosure, the cross-sections of 3D memory device 100 in FIGS. 2-25 and method 200 in FIG. 26 will be discussed together. It is understood that the operations shown in method 200 are not exhaustive and that other operations may be performed as well before, after, or between any of the illustrated operations. Further, some of the operations may be performed simultaneously, or in a different order than shown in FIGS. 2-25 and FIG. 26.

As shown in FIG. 2, a dielectric layer 104 ( ) is formed on a substrate 102, and a semiconductor layer 106 is formed on dielectric layer 104. In some implementations, substrate 102 may be a doped semiconductor layer. In some implementations, substrate 102 may be a silicon substrate. In some implementations, substrate 102 may include a wide array of semiconductor materials, such as silicon, germanium, gallium arsenide, indium phosphide, etc. In some implementations, substrate 102 may include an electrically non-conductive material, such as a glass, a plastic, or a sapphire wafer. In some implementations, dielectric layer 104 may include a layer of silicon oxide. In some implementations, semiconductor layer 106 may include a doped or undoped polysilicon layer. In some implementations, dielectric layer 104 and semiconductor layer 106 may be sequentially deposited by one or more thin film deposition processes including, but not limited to, chemical vapor deposition (CVD), physical vapor deposition (PVD), atomic layer deposition (ALD), or any combination thereof. A trench 108 may be formed in semiconductor layer 106. Trench 108 may overlap the slit opening formed in the later operations in a plan view of substrate 102. In some implementations, the size or the width of trench 108 may greater than the slit opening formed in the later operations. In some implementations, trench 108 may be formed by dry etch, wet etch, or other suitable processes.

In some implementations, dielectric layer 104 and semiconductor layer 106 may not be required, and trench 108 may be formed in substrate 102 by using dry etching, wet etching, or other suitable processes. In some implementations, the width of trench 108 may be greater than a width of a second opening 164 formed in the later operations. In some implementations, the width of trench 108 may be 30-200 nm greater than the width of second opening 164 formed in the later operations. In some implementations, the width of trench 108 may be equal to the width of second opening 164 formed in the later operations. In some implementations, the width of trench 108 may be less than the width of second opening 164 formed in the later operations.

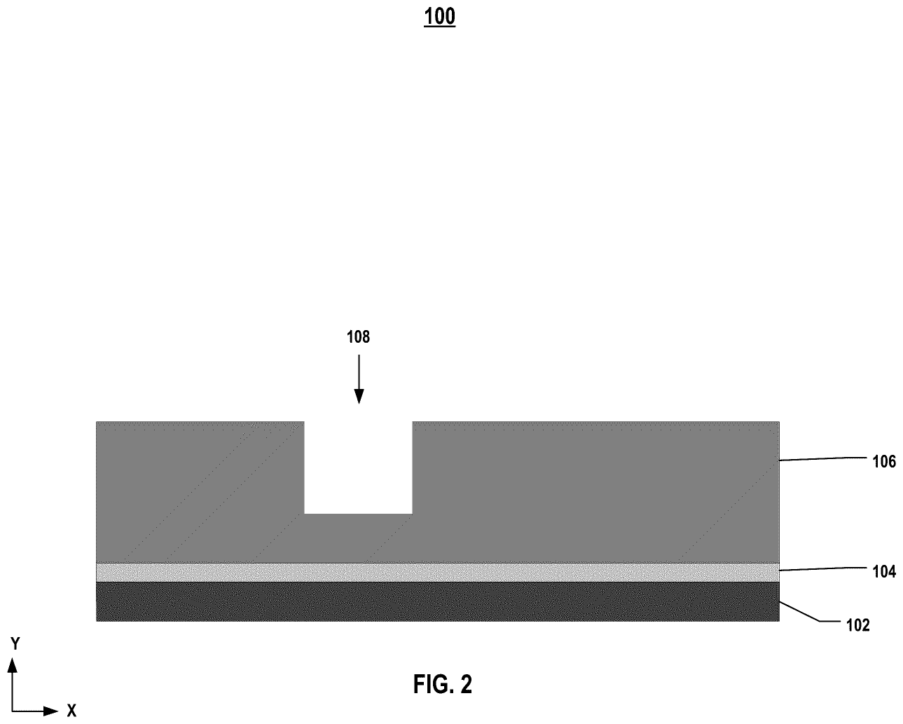

As shown in FIG. 3, a dielectric layer 110 (e.g., first dielectric layer) is formed in trench 108. In some implementations, dielectric layer 110 may include a silicon oxide layer and may be formed in trench 108 by CVD, PVD, ALD, or any combination thereof. In some implementations, after forming dielectric layer 110, a planarization operation, e.g., chemical mechanical polishing (CMP) process, may be performed to planarize the top surface of dielectric layer 110 and semiconductor layer 106.

In some implementations, trench 108 and dielectric layer 110 may not be required. In the present application, dielectric layer 110 is used for aligning two openings formed in the later operations. However, when other suitable processes, such as a photolithography operation, are used to align two openings, trench 108 and dielectric layer 110 may not be required.

In some implementations, dielectric layer 110 may include SiO, SiN, SiNO, Al2O3, or C. In some implementations, dielectric layer 110 may include materials other than substrate 102.

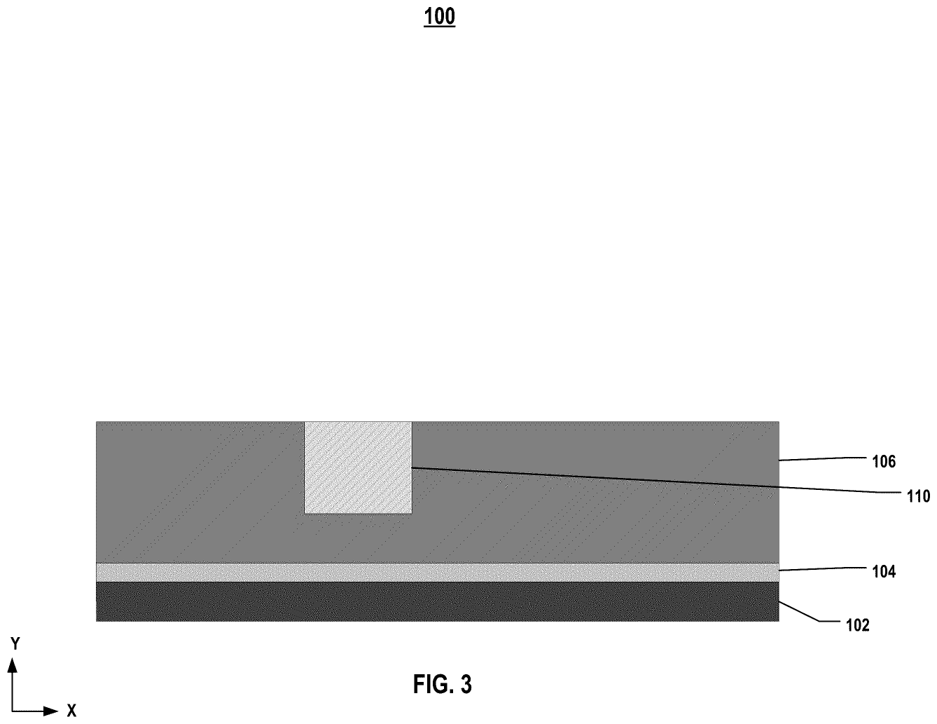

As shown in FIG. 4, a dielectric layer 112, a polysilicon layer 114, and a dielectric layer 116 are formed on dielectric layer 110 and semiconductor layer 106. In some implementations, dielectric layer 112 and/or dielectric layer 116 may include a layer of silicon oxide. In some implementations, polysilicon layer 114 may include a doped or undoped polysilicon layer. In some implementations, dielectric layer 112 may function as a stop layer when removing semiconductor layer 106 from the backside of 3D memory device 100 in later operations. In some implementations, polysilicon layer 114 may function as a stop layer when removing a bottom portion of the channel structure from the backside of 3D memory device 100 in later operations. In some implementations, dielectric layer 112, polysilicon layer 114, and dielectric layer 116 may be sequentially deposited by one or more thin film deposition processes including, but not limited to, CVD, PVD, ALD, or any combination thereof.

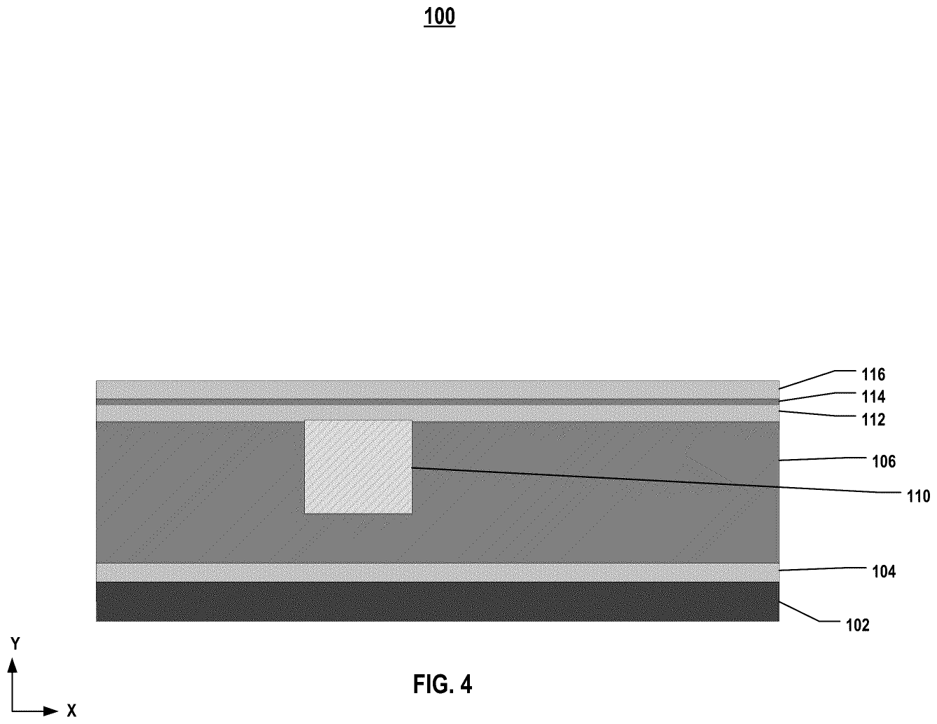

As shown in FIG. 5 and operation 202 in FIG. 26, a dielectric stack 118 including a plurality of sacrificial layers 122. A plurality of dielectric layers 120 (e.g., first dielectric layers) and the plurality of sacrificial layers 122 (e.g., first sacrificial layers) are alternatingly arranged. The dielectric/sacrificial layer pairs may include interleaved dielectric layers 120 and sacrificial layers 122 extending along a plane. In some implementations, each dielectric layer 120 may include a layer of silicon oxide, and each sacrificial layer 122 may include a layer of silicon nitride. The dielectric/sacrificial layer pairs may be formed by one or more thin film deposition processes including, but not limited to, CVD, PVD, ALD, or any combination thereof.

Further referring to FIG. 5, a channel hole 124 is formed in dielectric stack 118 along the y-direction. In some implementations, channel hole 124 may penetrate dielectric stack 118 and extend to semiconductor layer 106 (e.g., first semiconductor layer). In some implementations, fabrication processes for forming channel hole 124 may include wet etching and/or dry etching, such as deep reactive ion etching (DRIE).

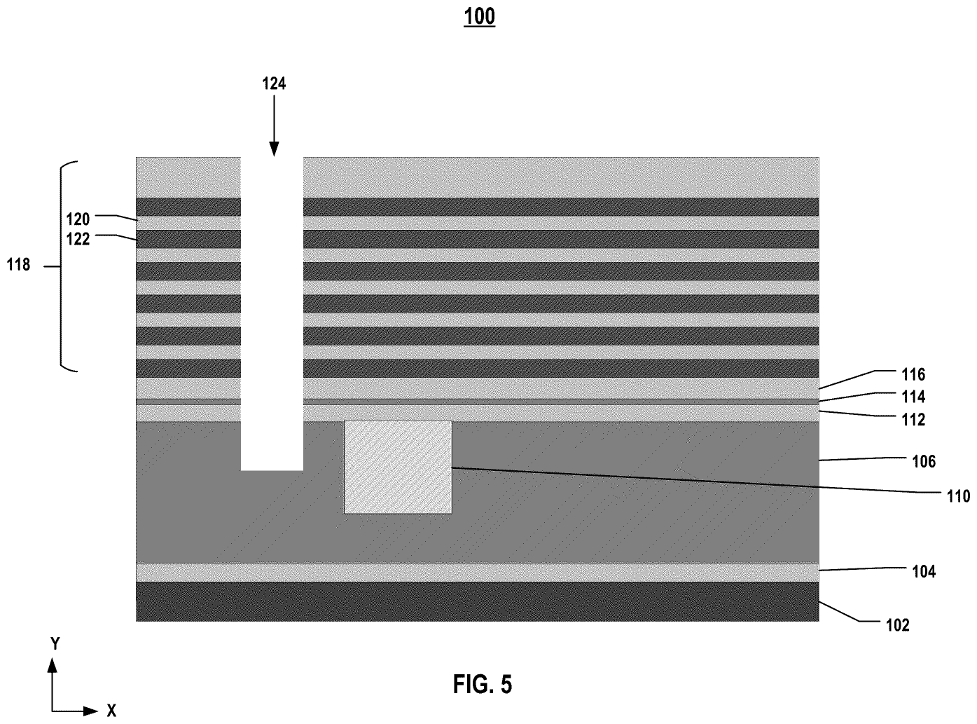

As shown in FIG. 5, FIG. 6 and operation 204 in FIG. 26, a plurality of channel structures 126 are formed in channel holes 124, respectively. Channel structure 126 may extend vertically through dielectric stack 118. Channel structure 126 may include memory film 134 and channel layer 136. In some implementations, channel structure 126 may also include dielectric core 138 in the center of channel structure 126. In some implementations, memory film 134 is a composite layer including tunneling layer 132, storage layer 130 (also known as a “charge trap layer”), and blocking layer 128. Channel structure 126 can have a cylinder shape (e.g., a pillar shape).

Dielectric core 138, channel layer 136, tunneling layer 132, storage layer 130, and blocking layer 128 are arranged radially from the center toward the outer surface of the pillar in this order, according to some implementations. In some implementations, tunneling layer 132 may include silicon oxide, silicon oxynitride, or any combination thereof. In some implementations, storage layer 130 may include silicon nitride, silicon oxynitride, silicon, or any combination thereof. In some implementations, blocking layer 128 may include silicon oxide, silicon oxynitride, high dielectric constant (high-k) dielectrics, or any combination thereof. In one example, memory film 134 may include a composite layer of silicon oxide/silicon oxynitride (or silicon nitride)/silicon oxide (ONO). In some implementations, a high-k dielectric layer 127 may be further formed between dielectric stack 118 and blocking layer 128.

As shown in FIG. 6, staircase structure 105 is formed at the outer region of dielectric stack 118. In some implementations, the outer region of dielectric stack 118 may include multiple staircase structures 105. The corresponding edges of dielectric stack 118 along the vertical direction away from the bottom of dielectric stack 118 (the positive y-direction) can be staggered laterally toward channel structure 126. In other words, the edges of dielectric stack 118 in staircase structures 105 can be tilted toward the inner region of dielectric stack 118. In some implementations, the length of the dielectric/sacrificial layer pairs increases from the top to the bottom. FIG. 6 illustrates a side staircase structure, however, in some implementations, the staircase structure may be located in the center of the dielectric stack 118 in a plane view, which is not limited here. For example, a core array region may be in the center of the dielectric stack 118, and two staircase regions are at the edges of the dielectric stack 118 along the z-direction, according to some implementations. For another example, a staircase region may be in the center of the memory stack, and two core array regions are at the edges of the memory stack in the word line direction, according to some implementations. In some implementations, the landing area and the dielectric layer may have a gap along the z-direction.

As shown in FIG. 6 and operation 206 in FIG. 26, an first opening 142 is formed from a top side of dielectric stack 118. In some implementations, first opening 142 extends along the y-direction and aligns dielectric layer 110 (e.g., second dielectric layer). In some implementations, first opening 142 may extend into a portion of dielectric stack 118. In other words, first opening 142 does not penetrate through dielectric stack 118. In some implementations, fabrication processes for forming first opening 142 may include wet etching and/or dry etching, such as DRIE.

In some implementations, the top layer in each level of staircase structure 105 (e.g., each dielectric/sacrificial layer pair in FIG. 6) is sacrificial layer 122. After sacrificial layer 122 (e.g., first sacrificial layer) is replaced by the conductive layers in the later operations, staircase structure 105 may be the word line fan-out. In some implementations, the formation of staircase structure 105 may include multiple etch operations. In some implementations, after forming staircase structure 105, a dielectric layer 144 may further be formed on the edge area of sacrificial layer 122 of each level of staircase structure 105. In some implementations, the material of dielectric layer 144 may be the same as sacrificial layer 122. As a result, as shown in FIG. 6, the thickness of the edge area of each level of staircase structure 105 may be greater than other areas. The edge area of each level of staircase structure 105 may function as the “landing area” for interconnection with the word lines of 3D memory device 100 in the later operations. Then, as shown in FIG. 6, a dielectric layer 146 is formed to cover staircase structure 105.

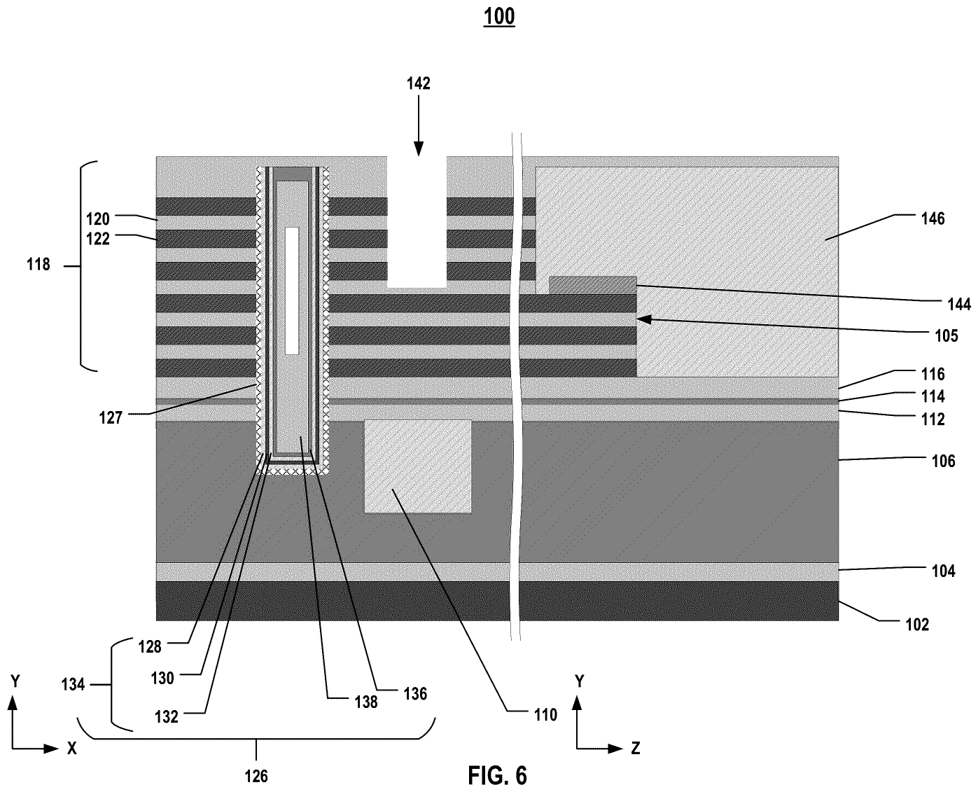

As shown in FIG. 7, a sacrificial layer 148 (e.g., second sacrificial layer) is formed in first opening 142. In some implementations, sacrificial layer 148 may extend into a portion of dielectric stack 118. In other words, sacrificial layer 148 does not penetrate through dielectric stack 118. In some implementations, sacrificial layer 148 may extend vertically in the top portion of dielectric stack 118. In some implementations, sacrificial layer 148 may be formed by CVD, PVD, ALD, or other suitable processes. In some implementations, sacrificial layer 148 may include silicon carbide. In some implementations, after forming sacrificial layer 148 in first opening 142, a planarization operation, e.g., CMP process, may be performed to planarize the top surface of sacrificial layer 148 and dielectric stack 118.

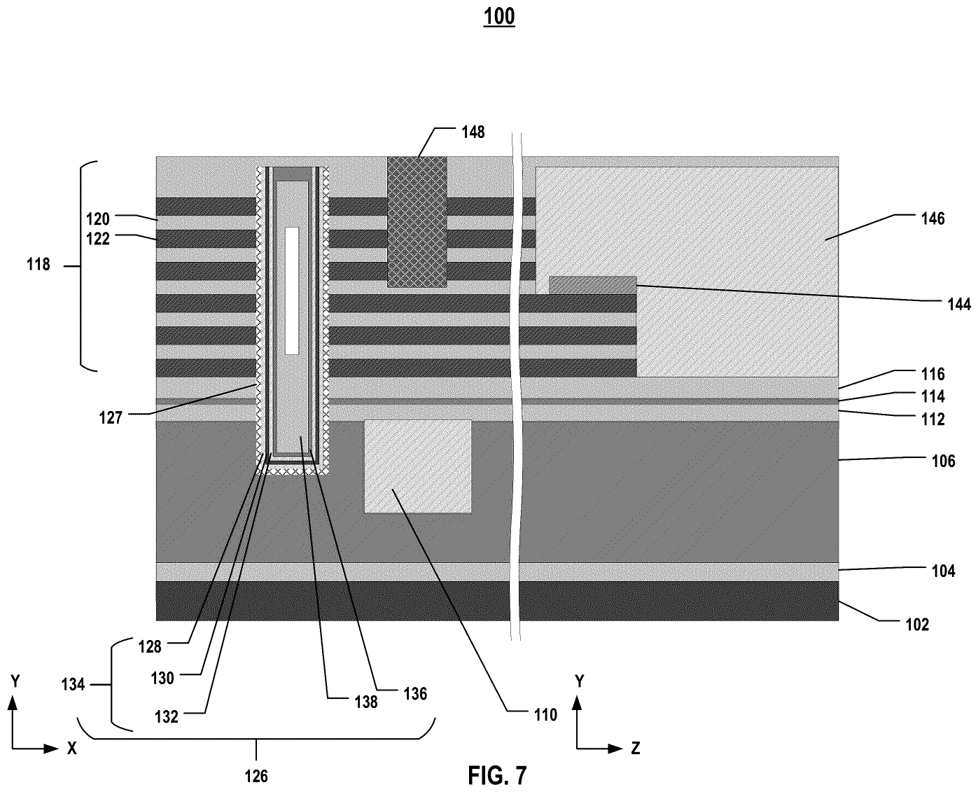

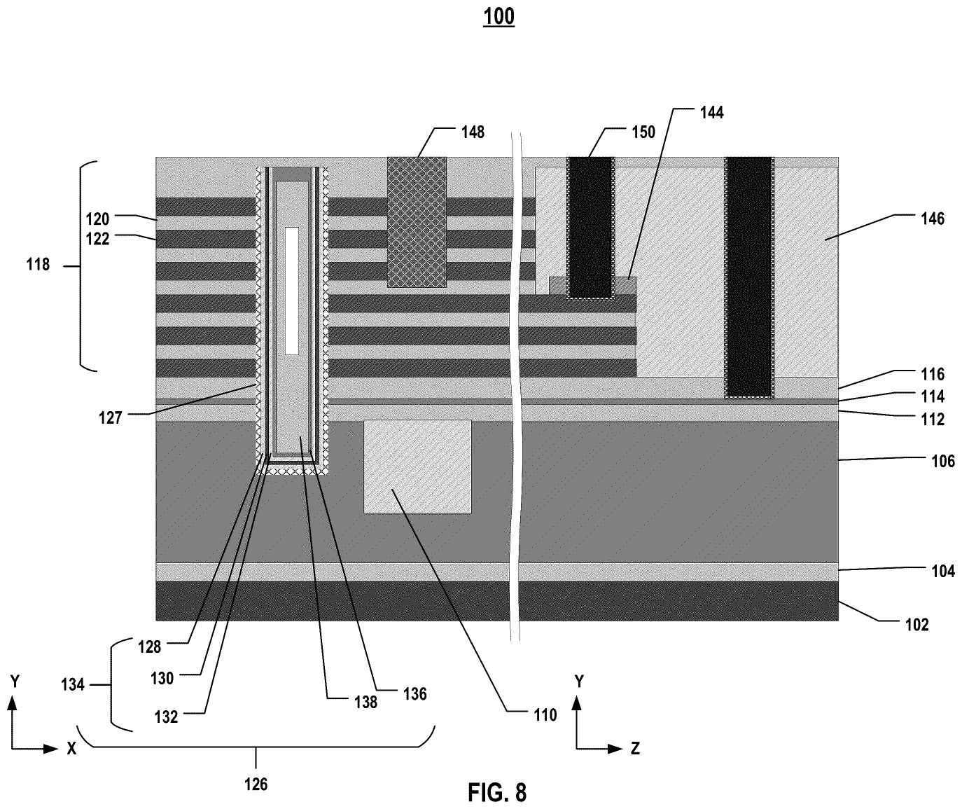

As shown in FIG. 8, a plurality of contact structures 150 are formed in dielectric layer 146 and extend vertically through dielectric layer 146. Each contact structure 150 is in contact with one of the plurality of sacrificial layers 122. In some implementations, a plurality of contact holes may be formed in dielectric layer 146 to expose dielectric layer 144 or sacrificial layer 122 by using dry etch, wet etch, or other suitable processes. Then, contact structures 150 may be formed in the contact holes by using CVD, PVD, ALD, or other suitable processes. In some implementations, contact structure 150 may include conductive materials including, but not limited to, W, Co, Cu, Al, polysilicon, doped silicon, silicides, or any combination thereof. Then, as shown in FIG. 9, peripheral device 152 is formed on dielectric stack 118 in electric contact with channel structures 126 and contact structures 150.

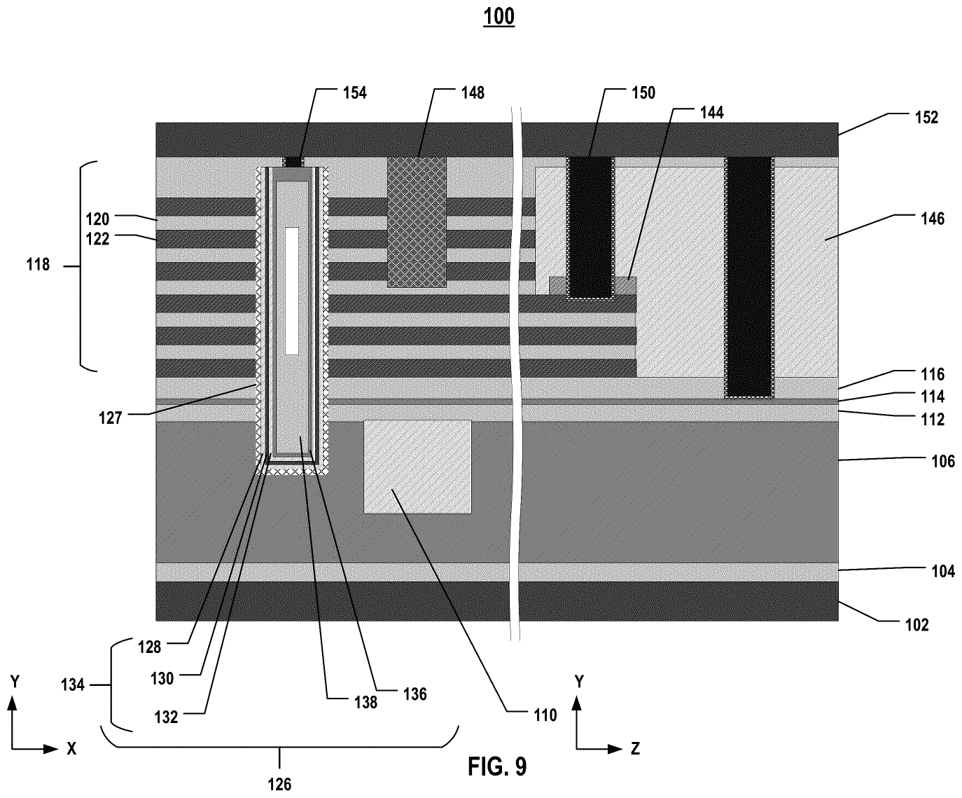

As shown in FIG. 10, a substrate removal operation is performed. In some implementations, substrate 102, dielectric layer 104, and semiconductor layer 106 are removed from the backside of 3D memory device 100. In some implementations, substrate 102, dielectric layer 104, and semiconductor layer 106 may be removed by multiple removal operations, such as the wet etch, dry etching, or other suitable processes, until being stopped by dielectric layer 112. In some implementations, substrate 102 and dielectric layer 104 may be removed by CMP process, and semiconductor layer 106 may be removed by wet etch, dry etching, or other suitable processes until being stopped by dielectric layer 112. In some implementations, substrate 102 and dielectric layer 104 may be peeled off, and semiconductor layer 106 may be removed by wet etch, dry etching, or other suitable processes until being stopped by dielectric layer 112. After the removal operations, as shown in FIG. 10, dielectric layer 110 and channel structure 126 are exposed.

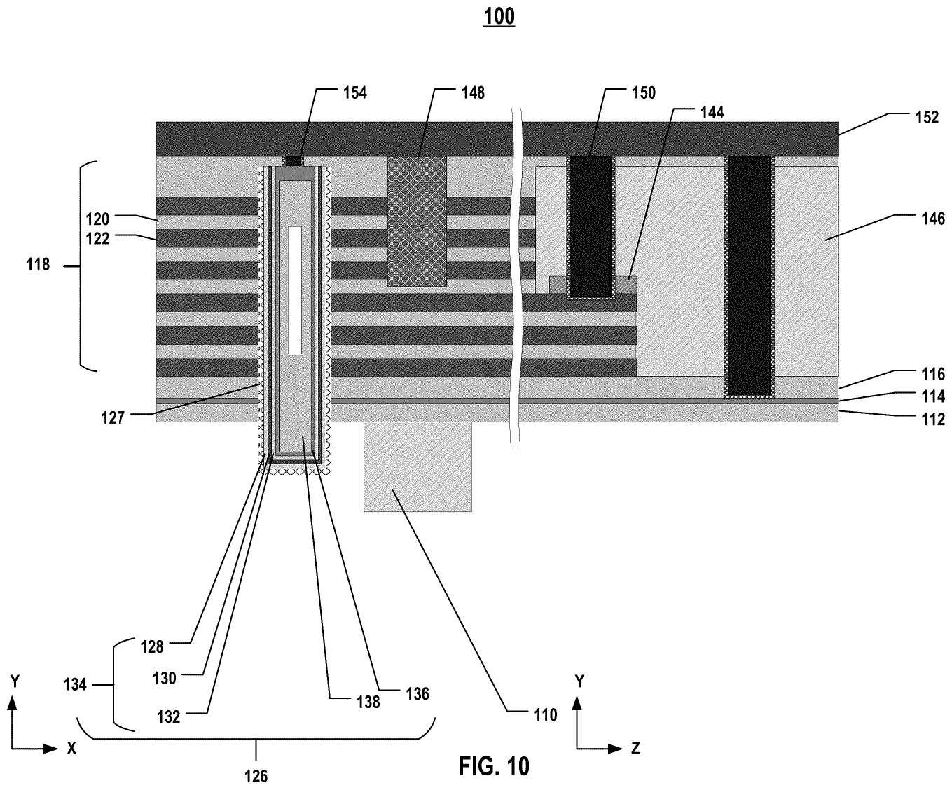

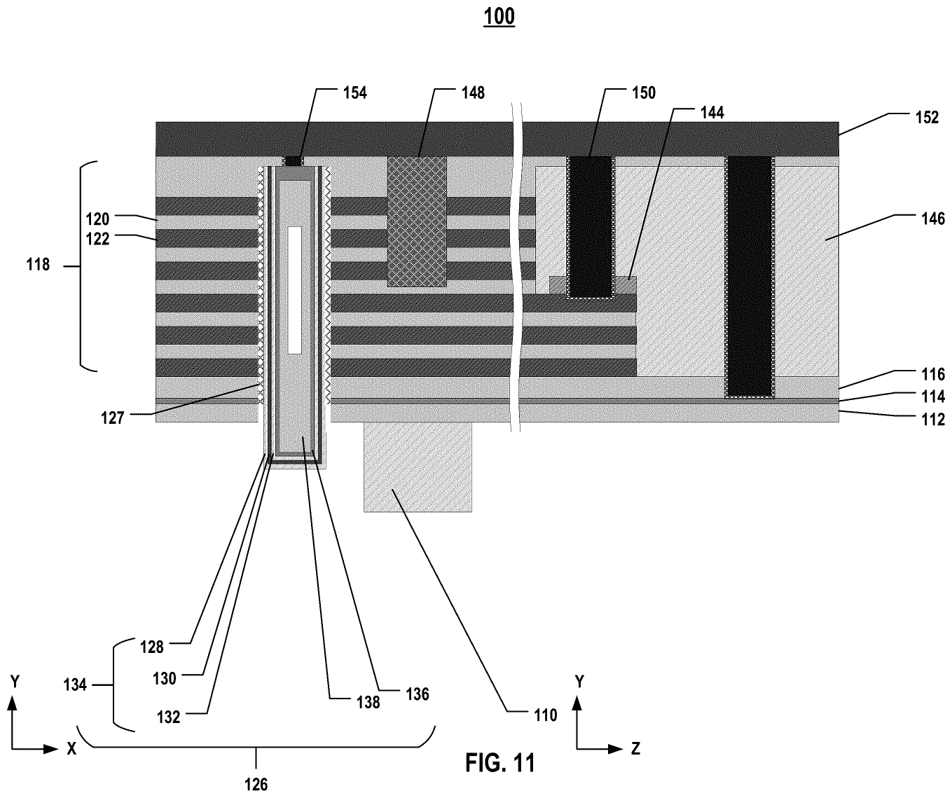

As shown in FIG. 11, the bottom portion of high-k dielectric layer 127 is removed, and then, as shown in FIG. 12, the bottom portion of memory film 134 and portions of dielectric layer 112 are removed. In some implementations, the bottom portion of high-k dielectric layer 127 and memory film 134 (including tunneling layer 132, storage layer 130, and blocking layer 128) may be removed by wet etch, dry etch, or other suitable processes. When removing memory film 134, portions of dielectric layer 112 may be removed together when dielectric layer 112 is formed by the same material with memory film 134, such as silicon oxide. After the removal of the bottom portion of high-k dielectric layer 127 and memory film 134, the bottom portion of channel layer 136 is exposed. In some implementations, after the removal operation, the bottom surface of high-k dielectric layer 127 may be lower than the bottom surface of dielectric layer 116. In some implementations, after the removal operation, the bottom surface of high-k dielectric layer 127 may be lower than the bottom surface of polysilicon layer 114.

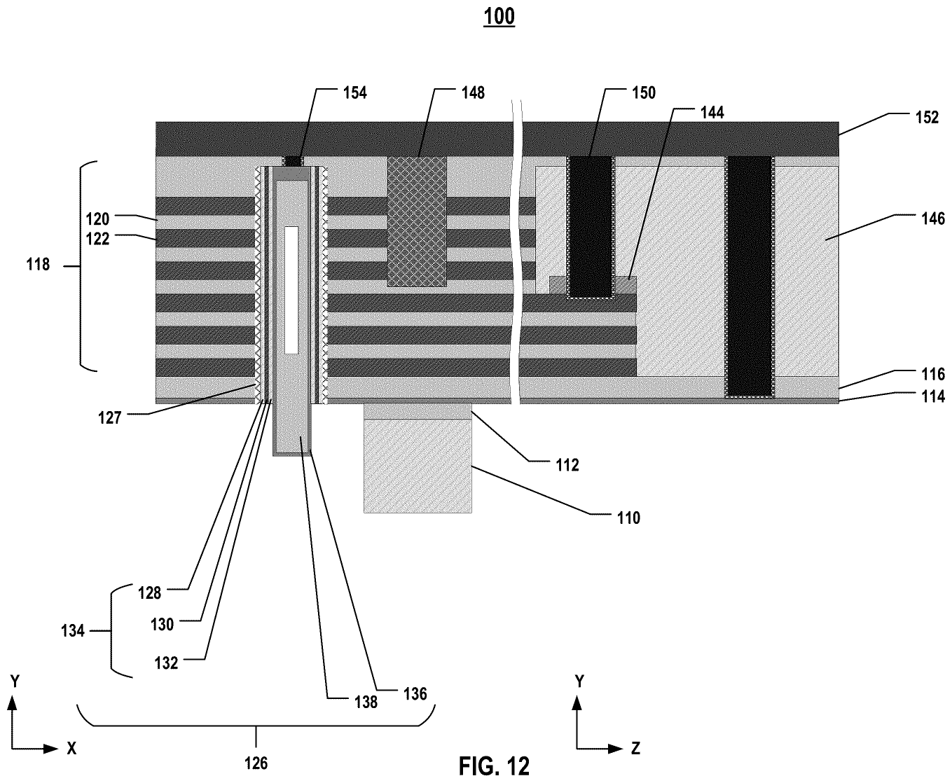

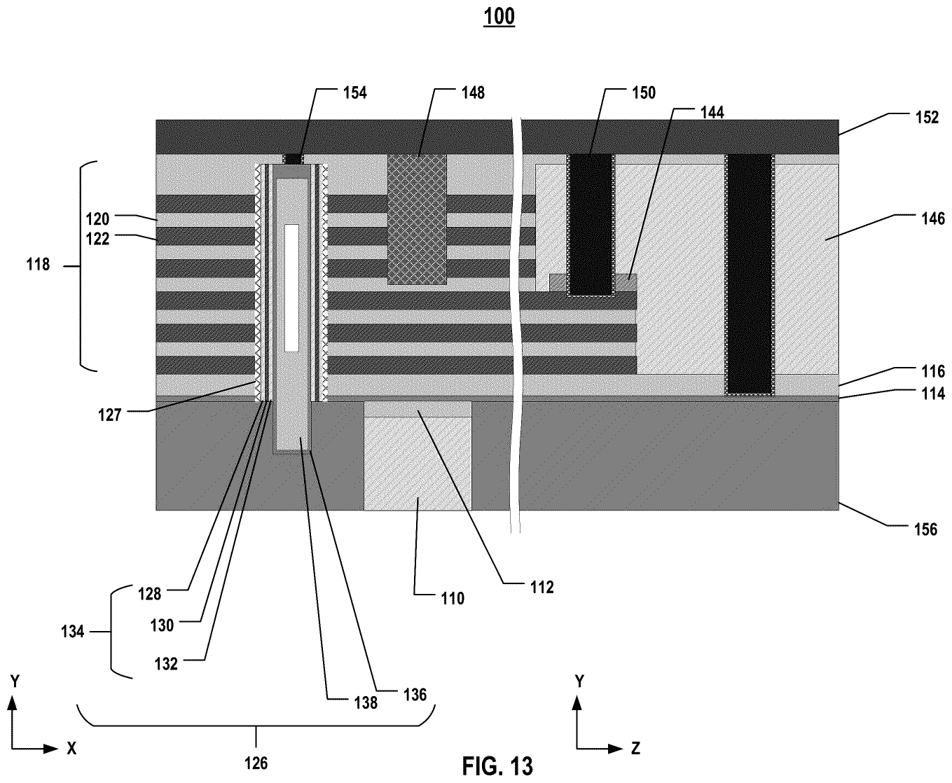

As shown in FIG. 13, a semiconductor layer 156 is formed over the exposed channel layer 136. In some implementations, semiconductor layer 156 may be a polysilicon layer. In some implementations, semiconductor layer 156 may be formed by CVD, PVD, ALD, or other suitable processes. In some implementations, semiconductor layer 156 may surround dielectric layer 110. Then, an etch-back operation may be performed to thin semiconductor layer 156, as shown in FIG. 14. The etch-back operation may be performed by using wet etch, dry etch, or other suitable processes.

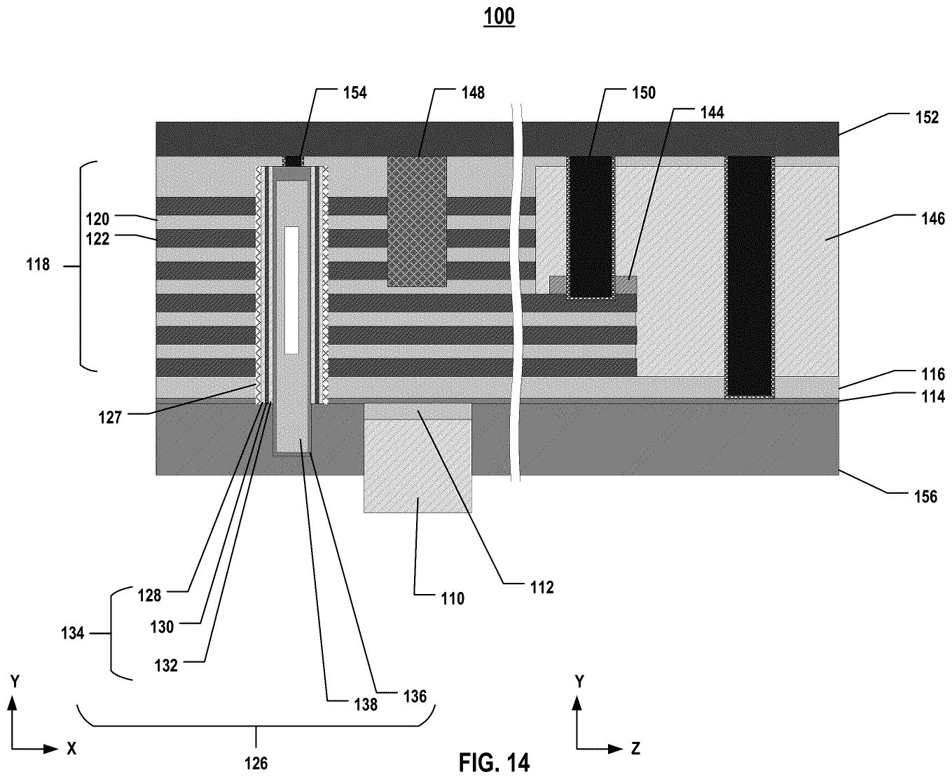

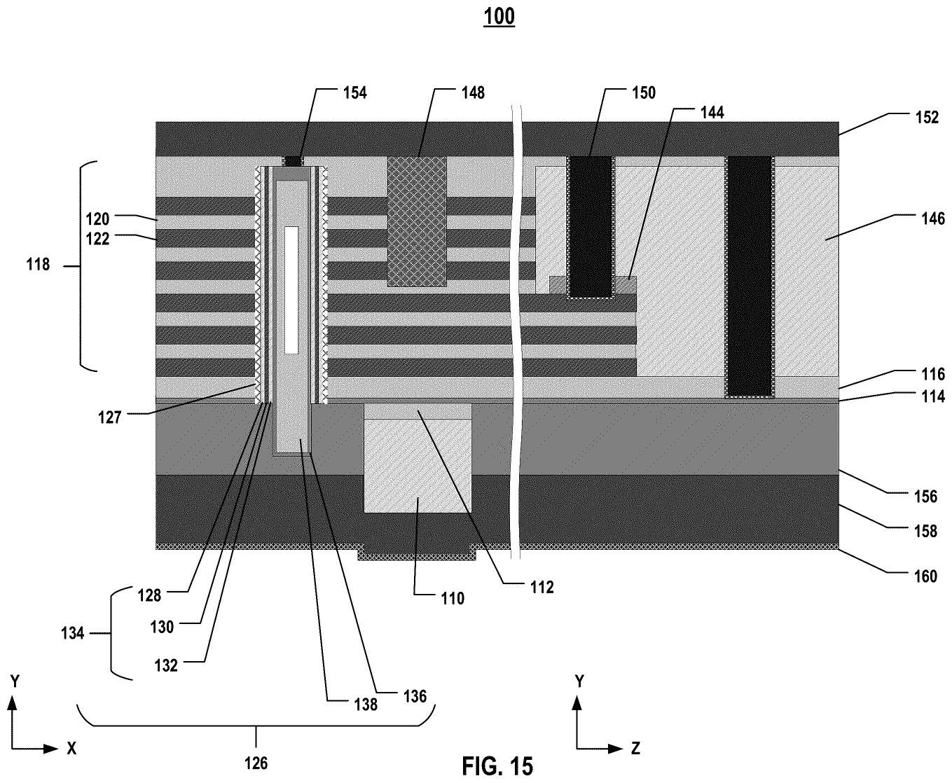

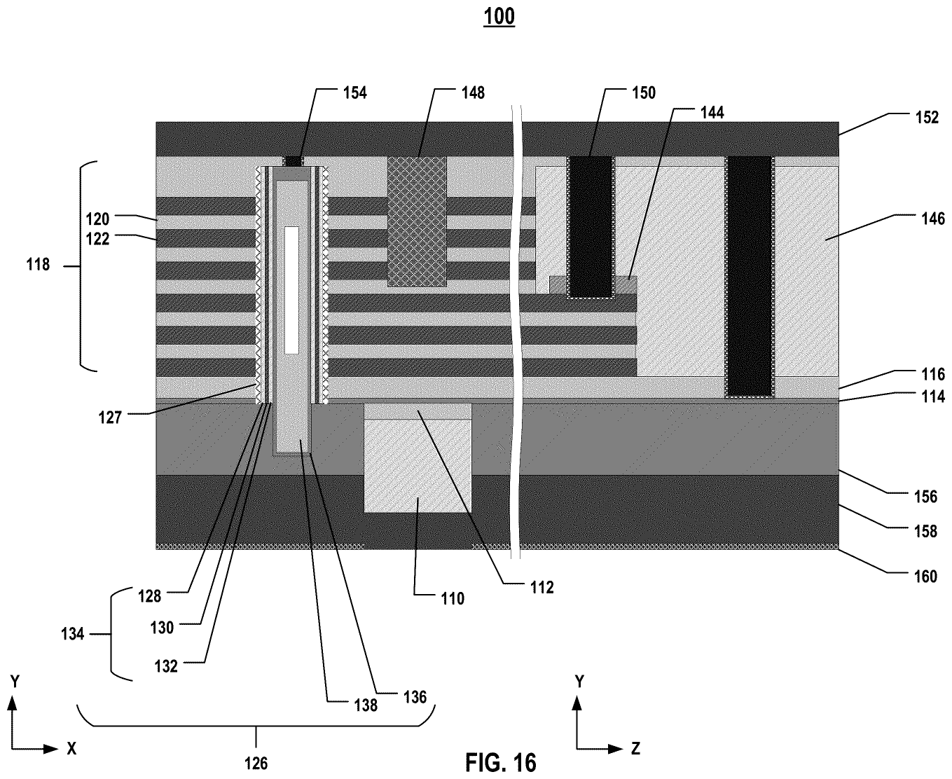

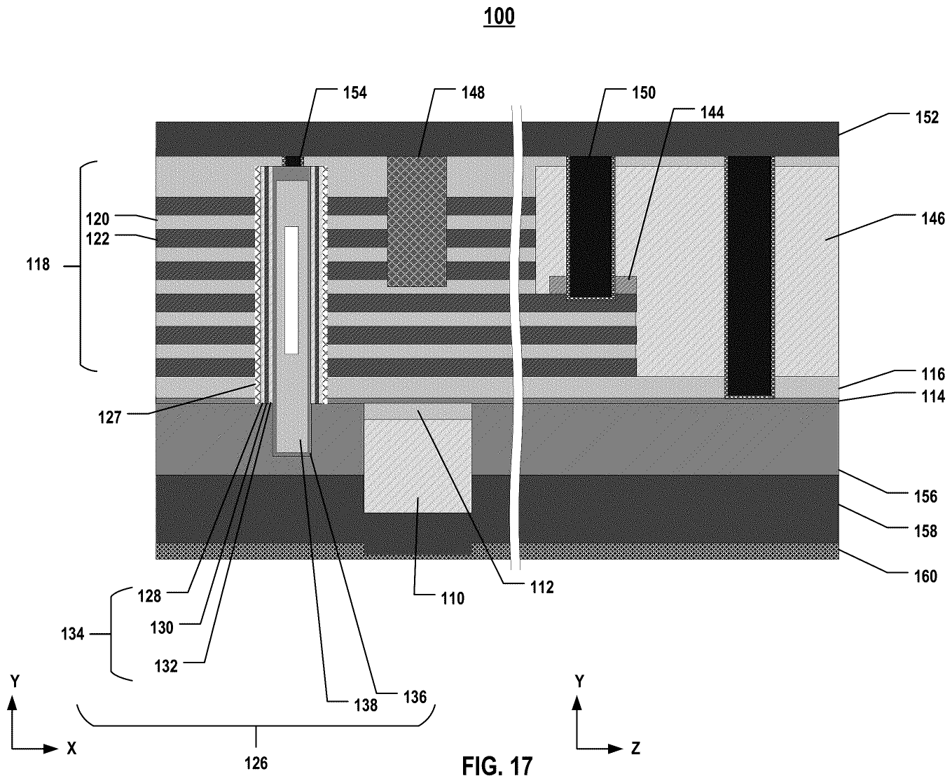

As shown in FIG. 15, a mask layer 158 is formed over thinned semiconductor layer 156, and a dielectric layer 160 is formed over mask layer 158. In some implementations, dielectric layer 160 may include silicon oxynitride (SiON). As shown in FIG. 16, a planarization operation, e.g., CMP process, may be performed to remove a portion of dielectric layer 160 and mask layer 158 and planarize dielectric layer 160 and mask layer 158. In some implementations, a further deposition operation may be optionally performed to thicken dielectric layer 160 after the CMP process, as shown in FIG. 17. As shown in FIG. 18, a photoresist 162 may be formed over thicken dielectric layer 160, and a pattern exposing the area of a portion of dielectric layer 110 may be formed.

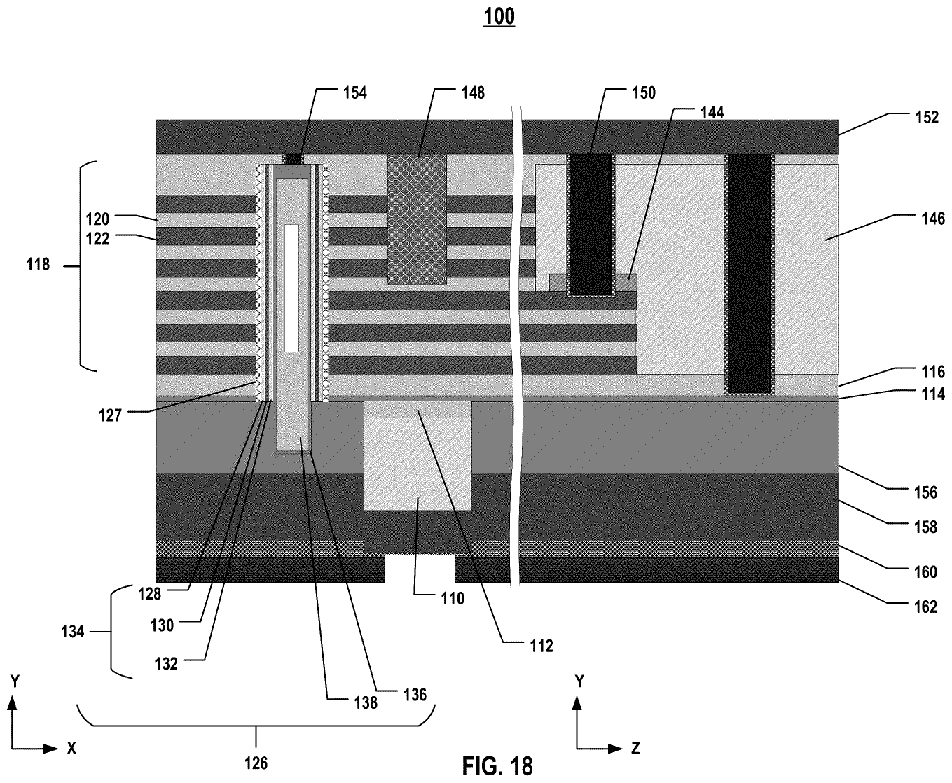

As shown in FIG. 19 and operation 208 in FIG. 26, a second opening 164 is formed from the bottom side of dielectric stack 118. In some implementations, second opening 164 may be formed by removing dielectric layer 110, dielectric layer 112, and a portion of dielectric stack 118. In some implementations, dielectric layer 110, dielectric layer 112, and a portion of dielectric stack 118 may be removed in one or multiple operations using dry etch, wet etch, or other suitable processes. Because sacrificial layer 148 (e.g., second sacrificial layer) is formed aligning dielectric layer 110 by forming first opening 142 aligning dielectric layer 110, second opening 164 can align sacrificial layer 148 when forming second opening 164 by removing dielectric layer 110. In other words, sacrificial layer 148 is formed from the top side of dielectric stack 118, and second opening 164 is formed from the bottom side of dielectric stack 118 exposing sacrificial layer 148. In some implementations, the width of second opening 164 is greater than the width of first opening 142 (the width of sacrificial layer 148). In some implementations, after forming second opening 164, photoresist 162 and dielectric layer 160 may be removed.

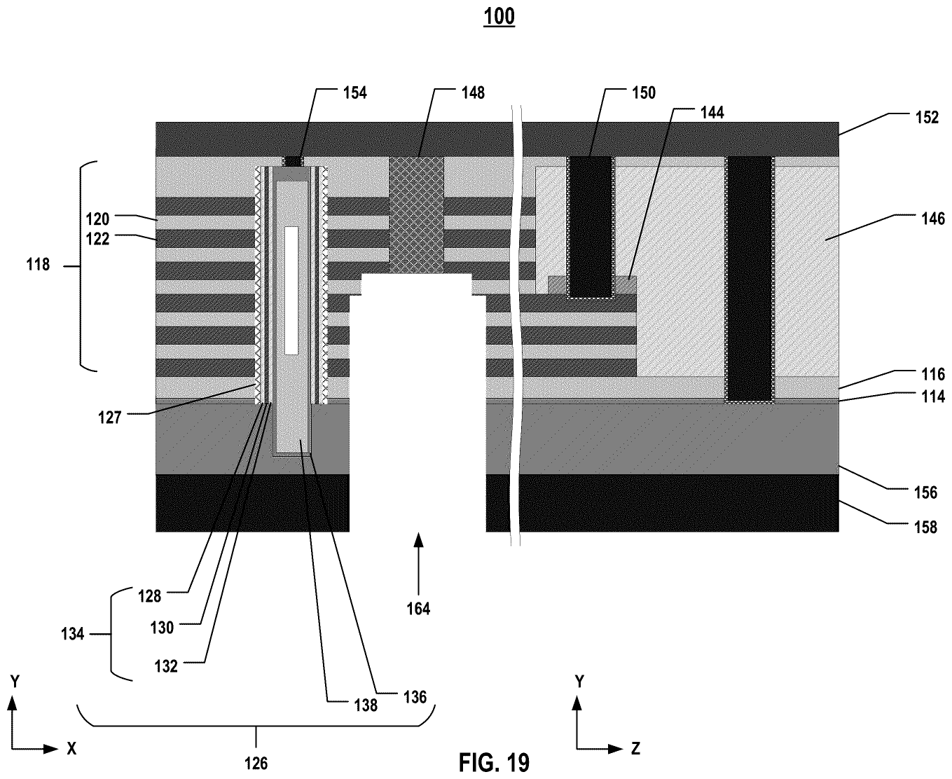

Then, as shown in FIG. 20, sacrificial layer 148 is removed from second opening 164, and a slit opening 165 is formed. In some implementations, mask layer 158 and sacrificial layer 148 may be removed in the same process. In some implementations, mask layer 158 and sacrificial layer 148 may be removed in different processes when mask layer 158 and sacrificial layer 148 are formed by different materials. In some implementations, after the removal of sacrificial layer 148, a recess operation may be performed on the sidewalls of slit opening 165 to remove a portion of sacrificial layers 122 and smoothen the edge of dielectric layers 120.

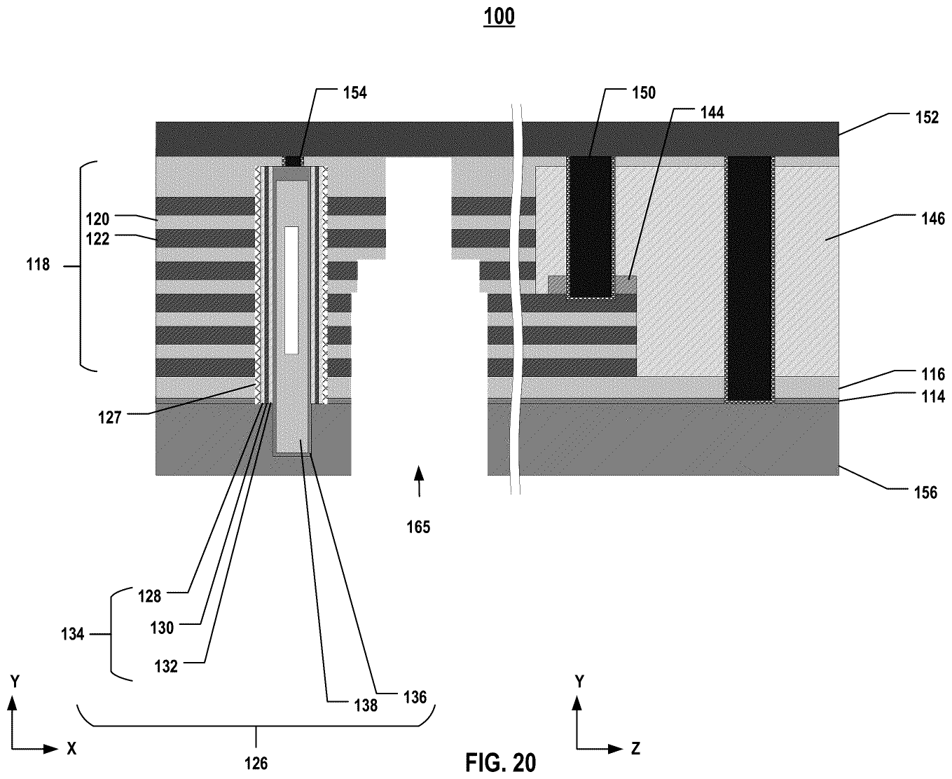

As shown in FIG. 21 and operation 210 in FIG. 26, a word line replacement operation is performed. Sacrificial layers 122 may be removed and replaced by conductive layers 166 (word lines). For example, sacrificial layers 122 may be removed by dry etch, wet etch, or other suitable processes to form a plurality of cavities. The word lines may be formed in the cavities by sequentially deposing the gate dielectric layer made from high-k dielectric materials, the adhesion layer including titanium/titanium nitride (Ti/TiN) or tantalum/tantalum nitride (Ta/TaN), and the gate conductor made from tungsten. After the word line replacement operation, stack structure 101 is formed.

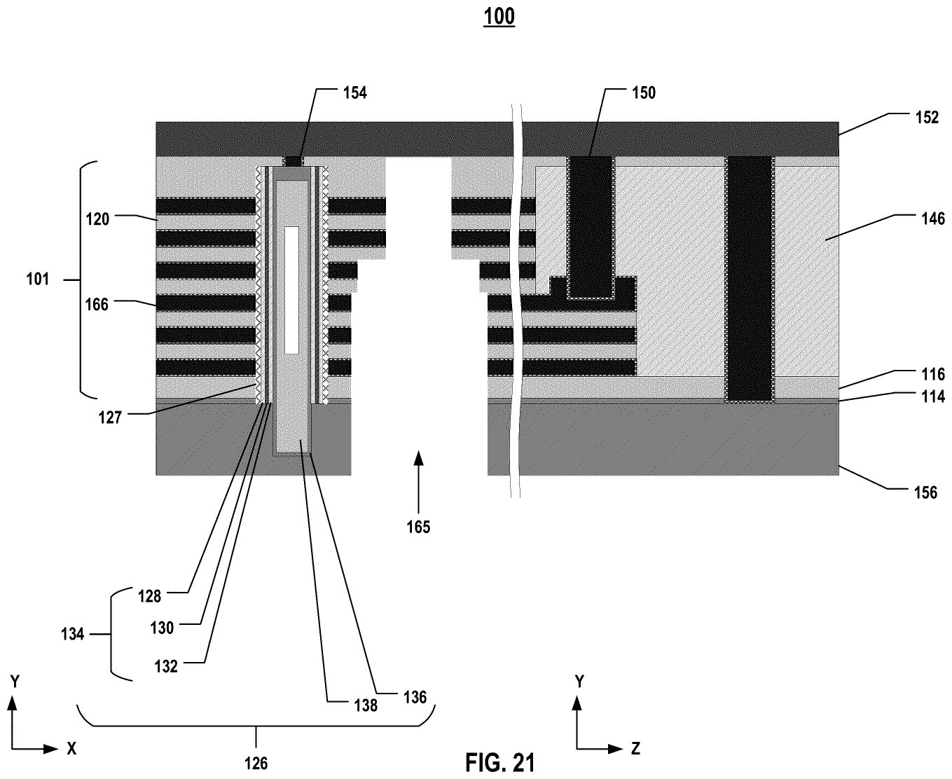

As shown in FIG. 22 and operation 212 in FIG. 26, slit structure 170 is formed in first opening 142 and second opening 164. Slit structures 170 may extend vertically along the y-direction through stack structure 101 and may also extend laterally along the z-direction to separate stack structure 101 into multiple fingers or multiple planes. In some implementations, slit structures 170 may include a slit contact, formed by filling the slit opening with conductive materials including but not limited to, W, Co, Cu, Al, polysilicon, silicides, or any combination thereof. Slit structures 170 may further include composite spacer 168 disposed laterally between slit contact 169 and stack structure 101 to electrically insulate slit contact 169 from surrounding conductive layers 166 of the stack structure. In some implementations, composite spacer 168 may include silicon oxide. In some implementations, slit contact 169 may be further extended or in contact with other distribution layers to form the contact path. In some implementations, slit structures 170 may be a supporting structure including dielectric materials.

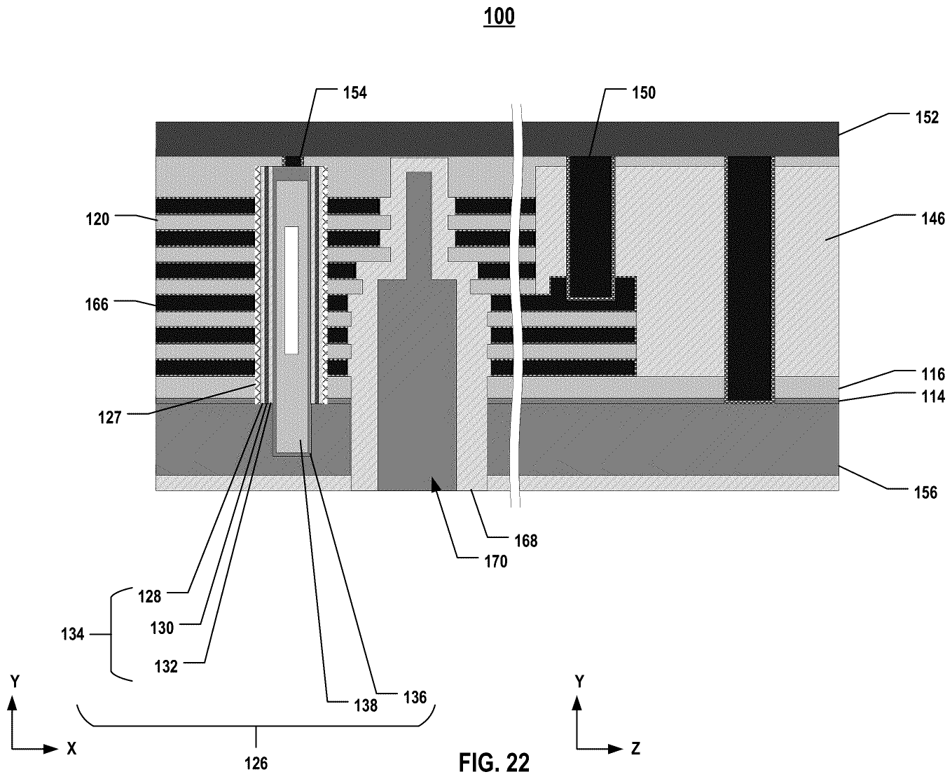

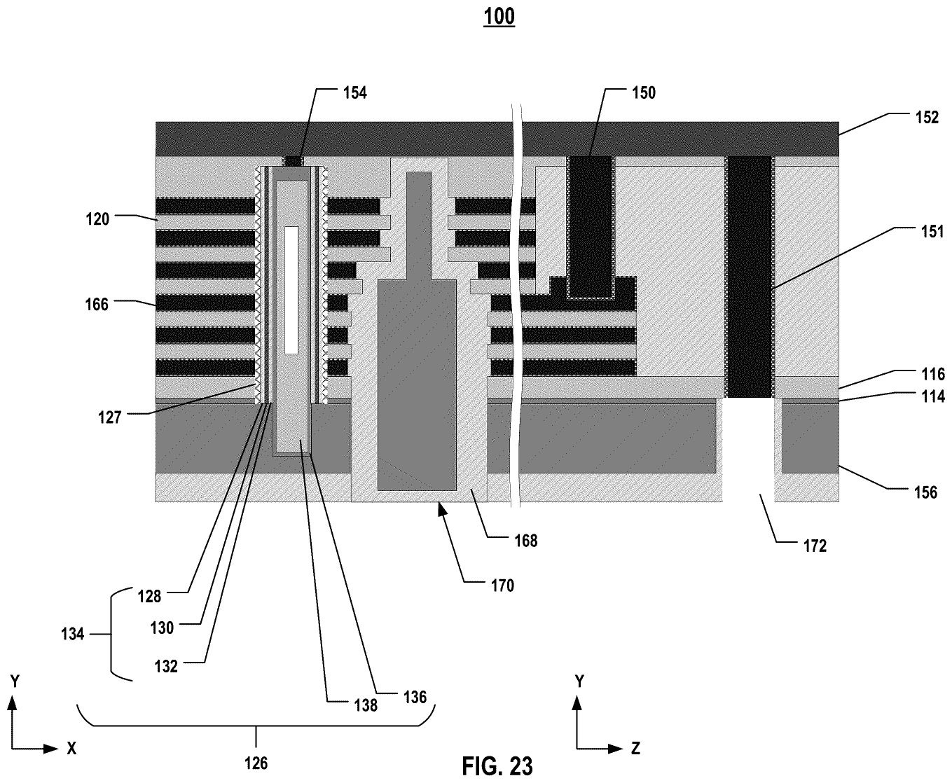

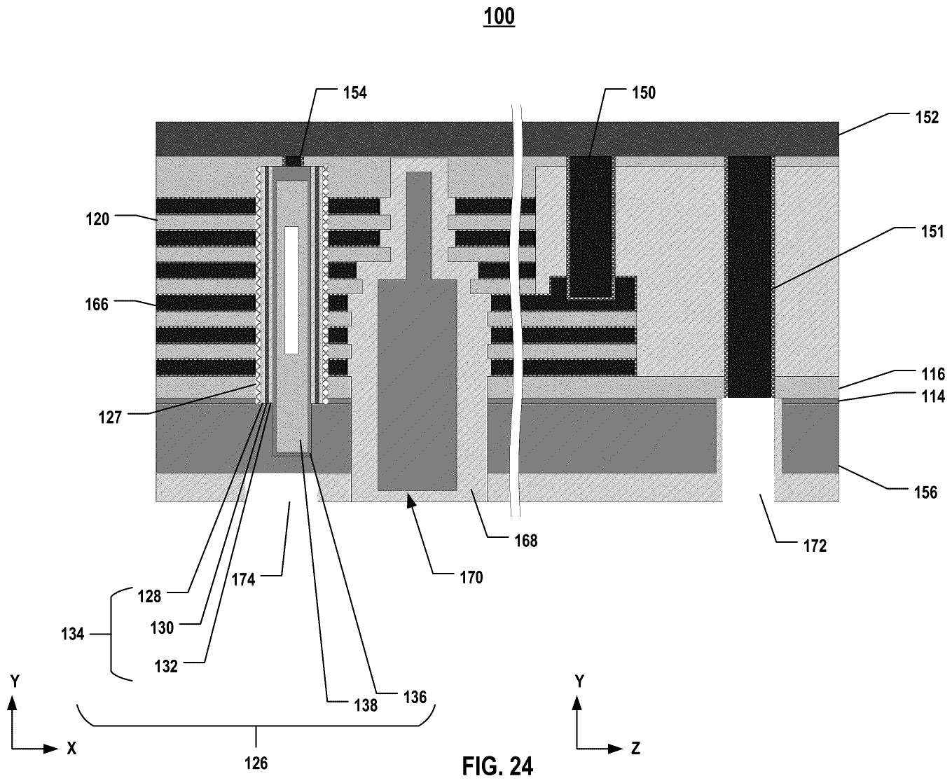

As shown in FIG. 23, an opening 172 is formed to expose the bottom portion of contact 151 by removing a portion of semiconductor layer 156. In some implementations, a dielectric layer may be formed on sidewalls of opening 172. Then, as shown in FIG. 24, an opening 174 is formed under channel structure 126 to expose semiconductor layer 156. As shown in FIG. 25, interconnection structure 176 is formed under 3D memory device 100 in electric contact with semiconductor layer 156 and contact 151. In other words, interconnect structure 176, and the peripheral device 152 are disposed at opposite sides of stack structure 101, and may be electrically connected through contact 151.

By using method 200 to manufacture 3D memory device 100, two openings may be formed from the top side and the bottom side of stack structure 101. A dielectric layer may be first formed in the substrate before forming stack structure 101, and after forming a first opening from the front side of stack structure 101, a sacrificial layer may be filled in the first opening. In some implementations, the substrate may further include other layers, such as a semiconductor layer 106 and a dielectric layer 104, as shown in FIG. 2. When forming a second opening from the bottom side of stack structure 101, the dielectric layer and/or the sacrificial layer may perform a self-alignment operation to form the second opening, and a complete slit opening will be formed when the second opening has been formed and the second opening is connected with the first opening. Here, the “front side” and the “bottom side” are referred to with respect to the y-direction when the substrate is on the bottom. The detailed operations of forming slit structure 170 will be discussed later. By forming the slit openings from both sides of stack structure 101, the difficulty of the etch operation to form slit structure 170 can be reduced, and slit structure 170 profile can be improved as well.

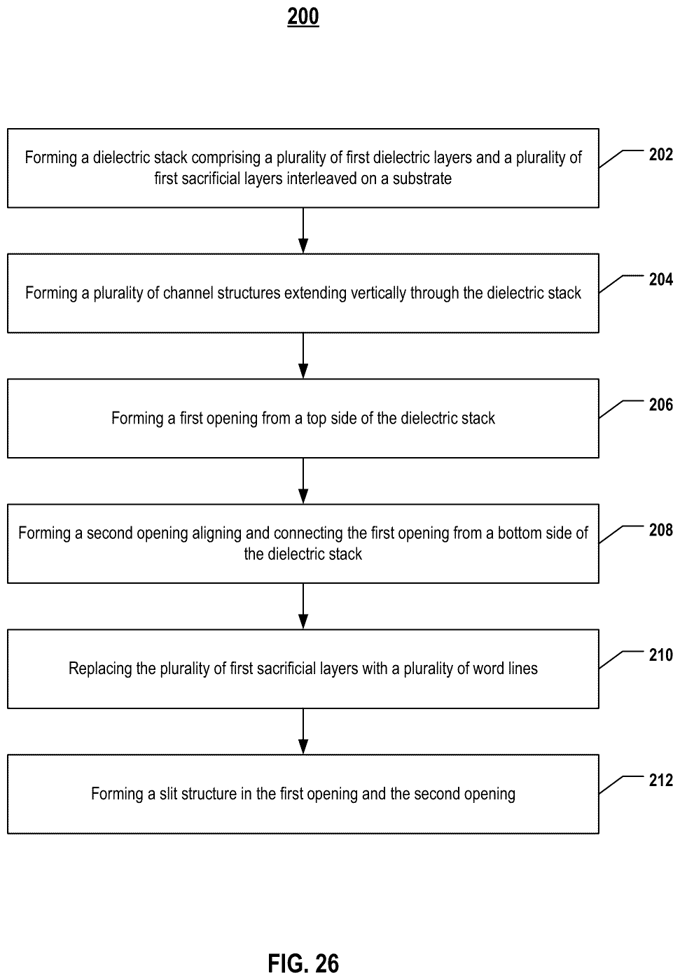

FIG. 27 illustrates a flowchart of another method 300 for forming 3D memory device 100, according to some aspects of the present disclosure. The cross-sections of 3D memory device 100 in FIGS. 2-25 can be used to explain the operations of method 300 as well. It is understood that the operations shown in method 300 are not exhaustive and that other operations may be performed as well before, after, or between any of the illustrated operations. Further, some of the operations may be performed simultaneously, or in a different order than shown in FIGS. 2-25 and FIG. 27.

As shown in FIG. 2 and operation 302 in FIG. 27, dielectric layer 104 is formed on substrate 102, and semiconductor layer 106 is formed on dielectric layer 104. In some implementations, substrate 102 may be a doped semiconductor layer. In some implementations, substrate 102 may be a silicon substrate. In some implementations, dielectric layer 104 may include a layer of silicon oxide. In some implementations, semiconductor layer 106 may include a doped or undoped polysilicon layer. In some implementations, dielectric layer 104 and semiconductor layer 106 may be sequentially deposited by one or more thin film deposition processes including, but not limited to, CVD, PVD, ALD, or any combination thereof. Trench 108 may be formed in semiconductor layer 106. In some implementations, trench 108 may be formed by dry etch, wet etch, or other suitable processes.

As shown in FIG. 3 and operation 304 in FIG. 27, dielectric layer 110 is formed in trench 108. In some implementations, dielectric layer 110 may include a silicon oxide layer and may be formed in trench 108 by CVD, PVD, ALD, or any combination thereof. In some implementations, after forming dielectric layer 110, a planarization operation, e.g., CMP process, may be performed to planarize the top surface of dielectric layer 110 and semiconductor layer 106.

As shown in FIG. 4, dielectric layer 112, polysilicon layer 114, and dielectric layer 116 are formed on dielectric layer 110 and semiconductor layer 106. In some implementations, dielectric layer 112 and/or dielectric layer 116 may include a layer of silicon oxide. In some implementations, polysilicon layer 114 may include a doped or undoped polysilicon layer. In some implementations, dielectric layer 112 may function as a stop layer when removing semiconductor layer 106 from the backside of 3D memory device 100 in later operations. In some implementations, polysilicon layer 114 may function as a stop layer when removing a bottom portion of the channel structure from the backside of 3D memory device 100 in later operations. In some implementations, dielectric layer 112, polysilicon layer 114, and dielectric layer 116 may be sequentially deposited by one or more thin film deposition processes including, but not limited to, CVD, PVD, ALD, or any combination thereof.

As shown in FIG. 5 and operation 306 in FIG. 27, dielectric stack 118 including a plurality of dielectric layers 120 and a plurality of sacrificial layers 122 alternatingly arranged is formed on dielectric layer 116. The dielectric/sacrificial layer pairs may include interleaved dielectric layers 120 and sacrificial layers 122 extending along the x-direction and a plane perpendicular to the y-direction. In some implementations, each dielectric layer 120 may include a layer of silicon oxide, and each sacrificial layer 122 may include a layer of silicon nitride. The dielectric/sacrificial layer pairs may be formed by one or more thin film deposition processes including, but not limited to, CVD, PVD, ALD, or any combination thereof.

Further referring to FIG. 5, channel hole 124 is formed in dielectric stack 118 along the y-direction. In some implementations, channel hole 124 may penetrate dielectric stack 118 and extend to semiconductor layer 106. In some implementations, fabrication processes for forming channel hole 124 may include wet etching and/or dry etching, such as DRIE.

As shown in FIG. 6 and operation 308 in FIG. 27, channel structure 126 is formed in channel hole 124. Channel structure 126 may extend vertically through dielectric stack 118. Channel structure 126 may include memory film 134 and channel layer 136. In some implementations, channel structure 126 may also include dielectric core 138 in the center of channel structure 126. In some implementations, memory film 134 is a composite layer including tunneling layer 132, storage layer 130 (also known as a “charge trap layer”), and blocking layer 128. Channel structure 126 can have a cylinder shape (e.g., a pillar shape).

Dielectric core 138, channel layer 136, tunneling layer 132, storage layer 130, and blocking layer 128 are arranged radially from the center toward the outer surface of the pillar in this order, according to some implementations. In some implementations, tunneling layer 132 may include silicon oxide, silicon oxynitride, or any combination thereof. In some implementations, storage layer 130 may include silicon nitride, silicon oxynitride, silicon, or any combination thereof. In some implementations, blocking layer 128 may include silicon oxide, silicon oxynitride, high dielectric constant (high-k) dielectrics, or any combination thereof. In one example, memory film 134 may include a composite layer of silicon oxide/silicon oxynitride (or silicon nitride)/silicon oxide (ONO). In some implementations, a high-k dielectric layer 127 may be further formed between dielectric stack 118 and blocking layer 128.

As shown in FIG. 6, first opening 142 is formed from a top side of dielectric stack 118. In some implementations, first opening 142 extends along the y-direction and vertically aligns dielectric layer 110. In other words, first opening 142 may overlap dielectric layer 110 in a plan view of 3D memory device 100. In some implementations, first opening 142 may extend into a portion of dielectric stack 118. In other words, first opening 142 does not penetrate through dielectric stack 118. In some implementations, fabrication processes for forming first opening 142 may include wet etching and/or dry etching, such as DRIE.

As shown in FIG. 6, staircase structure 105 is formed at the outer region of dielectric stack 118. In some implementations, the outer region of dielectric stack 118 may include multiple staircase structures 105. The corresponding edges of dielectric stack 118 along the vertical direction away from the bottom of dielectric stack 118 (the positive y-direction) can be staggered laterally toward channel structure 126. In other words, the edges of dielectric stack 118 in staircase structures 105 can be tilted toward the inner region of dielectric stack 118. In some implementations, the length of the dielectric/sacrificial layer pairs increases from the top to the bottom.

In some implementations, the top layer in each level of staircase structure 105 (e.g., each dielectric/sacrificial layer pair in FIG. 6) is sacrificial layer 122. After sacrificial layer 122 is replaced by the conductive layers in the later operations, staircase structure 105 may be the word line fan-out. In some implementations, the formation of staircase structure 105 may include multiple etch operations. In some implementations, after forming staircase structure 105, dielectric layer 144 may further be formed on the edge area of sacrificial layer 122 of each level of staircase structure 105. In some implementations, the material of dielectric layer 144 may be the same as sacrificial layer 122. As a result, as shown in FIG. 6, the thickness of the edge area of each level of staircase structure 105 may be greater than other areas. The edge area of each level of staircase structure 105 may function as the “landing area” for interconnection with the word lines of 3D memory device 100 in the later operations. Then, as shown in FIG. 6, dielectric layer 146 (e.g., third dielectric layer) is formed to cover staircase structure 105.

As shown in FIG. 7 and operation 310 in FIG. 27, sacrificial layer 148 is formed in first opening 142. In some implementations, sacrificial layer 148 may extend into a portion of dielectric stack 118. In other words, sacrificial layer 148 does not penetrate through dielectric stack 118. In some implementations, sacrificial layer 148 may extend vertically in the top portion of dielectric stack 118. In some implementations, sacrificial layer 148 may be formed by CVD, PVD, ALD, or other suitable processes. In some implementations, sacrificial layer 148 may include silicon carbide. In some implementations, after forming sacrificial layer in first opening 142, a planarization operation, e.g., CMP process, may be performed to planarize the top surface of sacrificial layer 148 and dielectric stack 118.

As shown in FIG. 8, contact structures 150 are formed in dielectric layer 146 and extend vertically through dielectric layer 146. Each contact structure 150 is in contact with one of the plurality of sacrificial layers 122. In some implementations, a plurality of contact holes may be formed in dielectric layer 146 to expose dielectric layer 144 by using dry etch, wet etch, or other suitable processes. Then, contact structures 150 may be formed in the contact holes by using CVD, PVD, ALD, or other suitable processes. In some implementations, contact structure 150 may include conductive materials including, but not limited to, W, Co, Cu, Al, polysilicon, doped silicon, silicides, or any combination thereof. Then, as shown in FIG. 9, peripheral device 152 is formed on dielectric stack 118 in electric contact with channel structures 126 and contact structures 150.

As shown in FIG. 10, a substrate removal operation is performed, and after the substrate removal operation, the bottom portion of channel structure 126 and dielectric layer 110 are exposed. In some implementations, substrate 102, dielectric layer 104, and semiconductor layer 106 are removed from the backside of 3D memory device 100. In some implementations, substrate 102, dielectric layer 104, and semiconductor layer 106 may be removed by multiple removal operations, such as the wet etch, dry etching, or other suitable processes, until being stopped by dielectric layer 112. In some implementations, substrate 102 and dielectric layer 104 may be removed by CMP process, and semiconductor layer 106 may be removed by wet etch, dry etching, or other suitable processes until being stopped by dielectric layer 112. In some implementations, substrate 102 and dielectric layer 104 may be peeled off, and semiconductor layer 106 may be removed by wet etch, dry etching, or other suitable processes until being stopped by dielectric layer 112.

As shown in FIG. 11, the bottom portion of high-k dielectric layer 127 is removed, and then, as shown in FIG. 12, the bottom portion of memory film 134 and portions of dielectric layer 112 are removed. In some implementations, the bottom portion of high-k dielectric layer 127 and memory film 134 (including tunneling layer 132, storage layer 130, and blocking layer 128) may be removed by wet etch, dry etch, CMP, or other suitable processes. When removing memory film 134, portions of dielectric layer 112 may be removed together when dielectric layer 112 is formed by the same material with memory film 134. After the removal of the bottom portion of high-k dielectric layer 127 and memory film 134, the bottom portion of channel layer 136 is exposed.

As shown in FIG. 13, semiconductor layer 156 is formed over the exposed channel layer 136. In some implementations, semiconductor layer 156 may be a polysilicon layer. In some implementations, semiconductor layer 156 may be formed by CVD, PVD, ALD, or other suitable processes. In some implementations, semiconductor layer 156 may surround dielectric layer 110. Then, an etch-back operation may be performed to thin semiconductor layer 156, as shown in FIG. 14. The etch-back operation may be performed by using wet etch, dry etch, or other suitable processes.

As shown in FIG. 15, mask layer 158 is formed over thinned semiconductor layer 156, and dielectric layer 160 is formed over mask layer 158. In some implementations, dielectric layer 160 may include silicon oxynitride (SiON). As shown in FIG. 16, a planarization operation, e.g., CMP process, may be performed to remove a portion of dielectric layer 160 and mask layer 158 and planarize dielectric layer 160 and mask layer 158. In some implementations, a further deposition operation may be optionally performed to thicken dielectric layer 160 after the CMP process, as shown in FIG. 17. As shown in FIG. 18, photoresist 162 may be formed over dielectric layer 160, and a pattern exposing the area of dielectric layer 110 may be formed.

As shown in FIG. 19 and operation 312 in FIG. 27, second opening 164 is formed from the bottom side of dielectric stack 118. In some implementations, second opening 164 may be formed by removing dielectric layer 110, dielectric layer 112, and a portion of dielectric stack 118. In some implementations, dielectric layer 110, dielectric layer 112, and a portion of dielectric stack 118 may be removed in one or multiple operations using dry etch, wet etch, or other suitable processes. Because sacrificial layer 148 is formed aligning dielectric layer 110 by forming first opening 142 aligning dielectric layer 110, second opening 164 can align sacrificial layer 148 when forming second opening 164 by removing dielectric layer 110. In other words, sacrificial layer 148 is formed from the top side of dielectric stack 118, and second opening 164 is formed from the bottom side of dielectric stack 118 exposing sacrificial layer 148. In some implementations, the width of second opening 164 is greater than the width of first opening 142 (the width of sacrificial layer 148). Then, as shown in FIG. 20, sacrificial layer 148 is removed from second opening 164.

As shown in FIG. 21, the word line replacement operation is performed, and sacrificial layers 122 may be removed and replaced by conductive layers 166 (word lines). For example, sacrificial layers 122 may be removed by dry etch, wet etch, or other suitable processes to form a plurality of cavities. The word lines may be formed in the cavities by sequentially deposing the gate dielectric layer made from high-k dielectric materials, the adhesion layer including titanium/titanium nitride (Ti/TiN) or tantalum/tantalum nitride (Ta/TaN), and the gate conductor made from tungsten. After the word line replacement operation, stack structure 101 is formed.

As shown in FIG. 22 and operation 314 in FIG. 27, slit structure 170 is formed in second opening 164. Slit structures 170 may extend vertically along the y-direction through stack structure 101 and may also extend laterally along the z-direction to separate stack structure 101 into multiple fingers. In some implementations, slit structures 170 may include a slit contact, formed by filling the slit opening with conductive materials including but not limited to, W, Co, Cu, Al, polysilicon, silicides, or any combination thereof. Slit structures 170 may further include composite spacer 168 disposed laterally between the slit contact and stack structure 101 to electrically insulate the gate line slit structure from surrounding conductive layers 166 (the gate conductors in stack structures). In some implementations, slit structures 170 may include dielectric materials when the slit contact is not required in 3D memory device 100.

As shown in FIG. 23, opening 172 is formed to expose the bottom portion of contact 151 by removing a portion of semiconductor layer 156. In some implementations, a dielectric layer may be formed on sidewalls of opening 172. Then, as shown in FIG. 24, opening 174 is formed under channel structure 126 to expose semiconductor layer 156. As shown in FIG. 25, interconnection structure 176 is formed under 3D memory device 100 in electric contact with semiconductor layer 156 and contact 151. In other words, interconnect structure 176, and the peripheral device 152 are disposed at opposite sides of stack structure 101, and may be electrically connected through contact 151.

By using method 300 to manufacture 3D memory device 100, the slit opening for forming slit structure 170 is formed in two operations, from the front side and the backside of stack structure 101. Dielectric layer 110 may be first formed in semiconductor layer 106 before forming dielectric stack 118, and after forming a slit opening (first opening 142) from the front side of dielectric stack 118, sacrificial layer 148 may be filled in the silt opening. When forming another slit opening (second opening 164) from the backside of dielectric stack 118, dielectric layer 110 and sacrificial layer 148 may perform a self-alignment operation to form slit structure 170. By forming the slit openings from both sides of dielectric stack 118, the difficulty of the etch operation to form slit structure 170 can be reduced, and slit structure 170 profile can be improved as well.

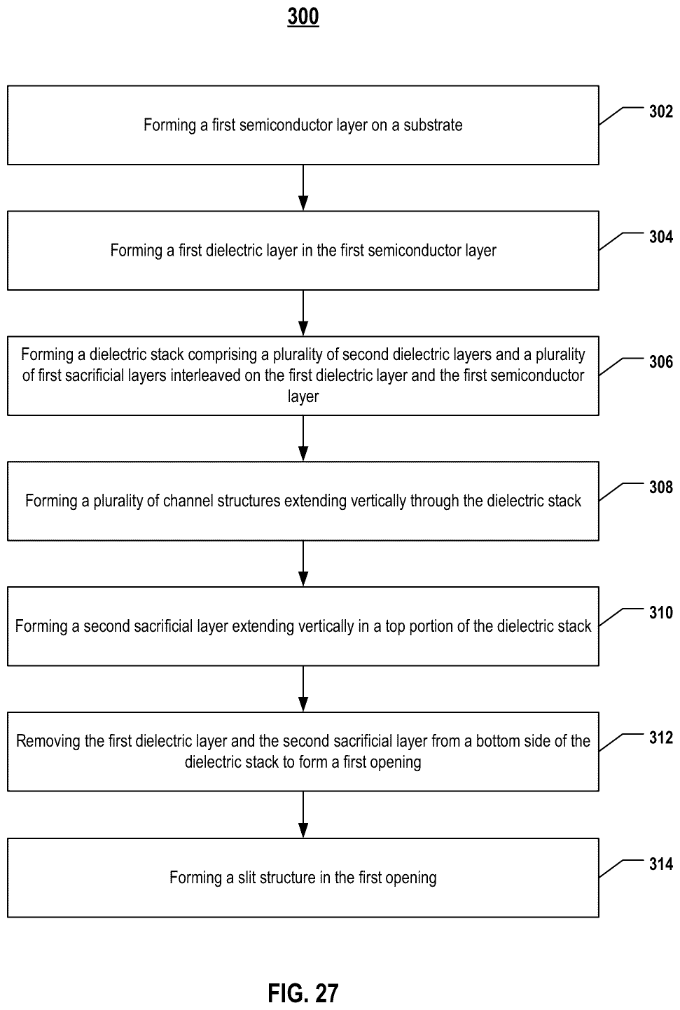

FIG. 28 illustrates a block diagram of an exemplary system 400 having a memory device, according to some aspects of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 28, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive data to or from memory devices 404.

Memory device 404 can be any memory device disclosed in the present disclosure. As disclosed above in detail, memory device 404, such as a NAND Flash memory device, may have a controlled and predefined discharge current in the discharge operation of discharging the bit lines. Memory controller 406 is coupled to memory device 404 and host 408 and is configured to control memory device 404, according to some implementations. Memory controller 406 can manage the data stored in memory device 404 and communicate with host 408. For example, memory controller 406 may be coupled to memory device 404, such as 3D memory device 100 described above, and memory controller 406 may be configured to control the operations of memory cells through the peripheral device. By forming the slit openings from both sides of dielectric stack 118, the process window of forming slit structure 170 of 3D memory device 100 will be greatly increased.

In some implementations, memory controller 406 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed for operating in a high duty-cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

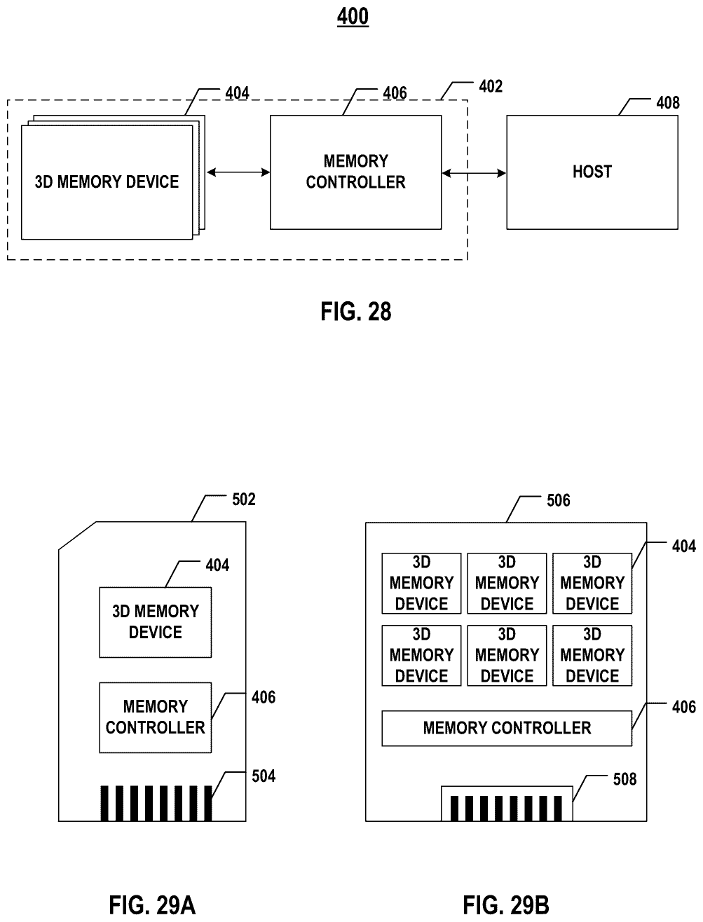

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 29A, memory controller 406 and a single memory device 404 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 502 can further include a memory card connector 504 coupling memory card 502 with a host (e.g., host 408 in FIG. 28). In another example as shown in FIG. 29B, memory controller 406 and multiple memory devices 404 may be integrated into an SSD 506. SSD 506 can further include an SSD connector 508 coupling SSD 506 with a host (e.g., host 408 in FIG. 28). In some implementations, the storage capacity and/or the operation speed of SSD 506 is greater than those of memory card 502.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a stack structure comprising interleaved conductive layers and dielectric layers;
channel structures, each of the channel structures extending through the stack structure; and
a slit structure extending through the stack structure,
wherein a first outer width of the slit structure in a bottom portion of the stack structure is greater than a second outer width of the slit structure in a top portion of the stack structure.

2. The 3D memory device of claim 1, further comprising:
a peripheral device disposed above the stack structure and in electric contact with the channel structures.

3. The 3D memory device of claim 2, further comprising:
an interconnect structure disposed below the stack structure,
wherein the interconnect structure and the peripheral device are disposed at opposite sides of the stack structure.

4. The 3D memory device of claim 1, further comprising:
contact structures extending to the stack structure, each of the contact structures in electric contact with one of the conductive layers, respectively.

5. The 3D memory device of claim 4, wherein the conductive layers are in electric contact with the contact structures at a portion of the conductive layers, and the portion of the conductive layers has a thickness greater than other portions of the conductive layers.

6. The 3D memory device of claim 4, wherein a stair-like structure is formed between the bottom portion of the stack structure and the top portion of the stack structure.

7. The 3D memory device of claim 4, wherein a smooth structure is formed between the bottom portion of the stack structure and the top portion of the stack structure.

8. The 3D memory device of claim 1, further comprising:
a peripheral device in electric contact with the channel structures through a distribution layer.

9. A memory system, comprising:
a three-dimensional (3D) memory device, comprising:
a memory device, comprising:
a stack structure comprising interleaved conductive layers and dielectric layers;
channel structures, each of the channel structures extending through the stack structure; and
a slit structure extending through the stack structure,
wherein a first outer width of the slit structure in a bottom portion of the stack structure is greater than a second outer width of the slit structure in a top portion of the stack structure; and
a memory controller coupled to the 3D memory device and configured to control operations of the 3D memory device.

10. A method for forming a three-dimensional (3D) memory device, comprising:
forming a dielectric stack comprising first dielectric layers and first sacrificial layers interleaved on a substrate;
forming channel structures extending through the dielectric stack;
forming a first opening from a top side of the dielectric stack;
forming a second opening aligning and connecting the first opening from a bottom side of the dielectric stack; and
forming a slit structure in the first opening and the second opening.

11. The method of claim 10, wherein a depth of the first opening is between ½ and ⅓ of a thickness of the dielectric stack.

12. The method of claim 10, further comprising:
replacing the first sacrificial layers with conductive layers.

13. The method of claim 10, wherein an outer width of the second opening is greater than an outer width of the first opening.

14. The method of claim 10, further comprises:
forming a first semiconductor layer on the substrate;
forming a second dielectric layer in the first semiconductor layer; and
forming the dielectric stack comprising the plurality of first dielectric layers and the plurality of first sacrificial layers interleaved on the first semiconductor layer and the second dielectric layer.

15. The method of claim 14, wherein forming the second dielectric layer in the first semiconductor layer, further comprises:
forming a trench in the first semiconductor layer; and
forming the second dielectric layer in the trench.

16. The method of claim 14, further comprises:
forming a staircase structure at the dielectric stack;
forming the first opening from the top side of the dielectric stack, the first opening aligning the second dielectric layer; and
forming a second sacrificial layer in the first opening.

17. The method of claim 16, wherein the second sacrificial layer comprises silicon carbide.

18. The method of claim 16, wherein forming the second opening aligning and connecting the first opening from the bottom side of the dielectric stack, further comprises:
removing the substrate and the first semiconductor layer;
forming a second semiconductor layer over the channel structures;
removing the second dielectric layer and a portion of the dielectric stack from the bottom side of the dielectric stack to expose the second sacrificial layer; and
removing the second sacrificial layer in the first opening from the bottom side of the dielectric stack.

19. The method of claim 18, wherein removing the second dielectric layer and the portion of the dielectric stack from the bottom side of the dielectric stack, further comprises:
performing a removal operation to remove the second dielectric layer and the portion of the dielectric stack until being stopped by the second sacrificial layer.

20. The method of claim 19, further comprising:
performing a recess operation on sidewalls of the first opening and the second opening to remove a portion of the first sacrificial layers.
